(19) United States
(12) Patent Application Publication
(10) Pub. No.: US 2021/0047721 A1
(43) Pub. Date: Feb. 18, 2021

(54) TI ALLOY NANO COMPOSITE COATING-FILM AND MANUFACTURING METHOD THEREFOR

(71) Applicant: LG Electronics Inc., Seoul (KR)

(72) Inventors: Joungwook KIM, Seoul (KR); Kyoung Jin KU, Seoul (KR); Hangjin BAN, Seoul (KR)

(21) Appl. No.: 16/964,473

(22) PCT Filed: Jan. 23, 2019
(86) PCT No.: PCT/KR2019/000981

§ 371 Date: Jul. 23, 2020

(30) Foreign Application Priority Data
Jan. 23, 2018 (KR) 10-2018-0008484
Jan. 23, 2018 (KR) 10-2018-0008485
Jan. 23, 2018 (KR) 10-2018-0008486
Jan. 23, 2018 (KR) 10-2018-0008487

(51) Int. Cl. C23C 14/14; C23C 14/34

(52) U.S. Cl. CPC C23C 14/14; B82Y 30/00; C23C 14/34

(57) ABSTRACT

The present invention relates to: Ti alloy coating-film having excellent adherence with a base material, low friction resistance, and excellent hardness and elastic modulus characteristics; a method for manufacturing the coating-film, and a compressor comprising a component to which the coating-film is applied. According to the present invention, provided is the coating-film having: an amorphous matrix comprising Ti as a main component; and a nano composite microstructure including nanocrystals comprising TiN components dispersed in the matrix, thereby having an effect of increasing the ratio of H/E (hardness/elastic modulus) so as to enable the durability of the coating-film to improve.

### TECHNICAL FIELD

The present disclosure relates to a Ti alloys nanocomposites coating-film having an excellent adhesive strength to a base material, a low friction resistance, a high hardness and an excellent elastic modulus characteristic, a method of manufacturing the coating film, and a compressor including a part to which the coating film is applied.

### BACKGROUND ART

The driving parts or sliding members of various mechanical devices including an automobile engine require an excellent lubricating property due to relative motion between the parts.

In addition, home appliances such as an air conditioner and a refrigerator generally include mechanical devices such as a compressor. Since such a compressor utilizes a principle of applying mechanical energy to a fluid by compressing the fluid, reciprocating or rotating motion is essential to compress the fluid.

The operation of the compressor inevitably involves friction or vibration between mechanical elements constituting the above-mentioned compressor. For example, in a compressor operating on a reciprocating basis such as a reciprocating compressor, the friction between a piston and a cylinder may not be avoided.

Generally, to improve friction in the compressor, first, a separate mechanical component, such as a gas bearing, is used to reduce friction resistance. In addition, to also reduce the friction resistance between the piston and the bearing, a coating film is formed.

Conventionally, as a coating film, a liquid lubricating film has been commonly used. However, in recent years, there are on-going efforts to reduce friction and/or abrasion generally by using a solid coating film on a friction surface between parts.

The solid coating film that reduces friction also has a certain level of hardness and a high adhesive strength to a base material, as well as a friction property. As a material capable of satisfying the above-described properties, ceramic materials based on a nitride or carbide and diamond-like carbon (DLC) are used.

Meanwhile, recently, with the trend of miniaturization of home appliances, compact and high-speed compressors are rapidly increasing. The compact and high-speed compressors eventually mean that the conditions under which the compressors are operated become more and more severe. Particularly, a compressor designed for compact and high-speed conditions should not deteriorate under severe operating conditions to exhibit efficiency equal to or more than a large compressor.

However, most of the components for a conventional solid coating film have technical limitations for use in compact and high-speed compressors.

For example, a ceramic-based coating film has a very high surface hardness, which is advantageous for abrasion resistance, but generally has a high elastic modulus of approximately 400 to 700 MPa. The high elastic modulus of the ceramic material shows a large difference from the matrix of a metal component on which a ceramic material is coated or the elastic modulus of a different metal part involved in friction of the ceramic coating film, and such difference may cause a problem in durability of the matrix or other metal parts having a low elastic modulus.

When a part having an interface at which the friction occurs elastically absorbs stress that may be generated during reciprocation of a piston, it may reduce not only friction and abrasion, but may also significantly enhance the dimensional stability of the part. Furthermore, when the elastic strain of a part increases, the fracture toughness of the part increases. The improved fracture toughness may significantly improve the reliability of a part. However, the ceramic material has a disadvantage of low elastic strain.

Meanwhile, in the case of DLC, the improvement in abrasion loss compared with conventional Lubrite coating has been reported, but due to the lack of affinity to an oil additive used in a compressor, there is a limit to improving a low speed operation characteristic.

Therefore, there are increasing demands for a solid coating film or part having a novel component, which is able to replace a conventional solid coating film or part and has an excellent elastic deformation ability, and a compressor to which the solid coating film or part is applied.

In addition, there is a need to develop technology that allows a solid coating film having a low elastic modulus, high hardness and high elastic deformation ability to be attached to a base material with an excellent adhesive strength.

A related prior art, Korean Unexamined Patent Application Publication No. 10-2014-0145219 discloses a Zr-based metallic glass composition having a glass forming ability (GFA).

### DISCLOSURE

### Technical Problem

The present disclosure is directed to providing, in a part such as a compressor for various mechanical devices and air-conditioning systems, for example, such as an air conditioner and a refrigerator, a coating film having a novel component and a microstructure to improve a friction property and abrasion resistance, and a method of manufacturing the same.

Particularly, the present disclosure is directed to providing a coating film having an improved glass forming ability (GFA) to obtain an amorphous coating film having a Ti-rich composition with a high hardness as a matrix, and a method of manufacturing the same.

Furthermore, the present disclosure is directed to providing a method of manufacturing a coating film having an excellent adhesive strength to a base material and excellent abrasion resistance (hardness/elastic modulus ratio) in a coating film including an amorphous matrix having a Ti-rich composition with a high hardness.

In addition, the present disclosure is directed to providing various mechanical devices and compressors, which have improved friction and abrasion properties, a running-in property and reliability, compared with the conventional art, by providing a part or compressor on which the coating film is formed.

### Technical Solution

According to one aspect of the present disclosure for providing a coating film including a novel component and a microstructure to enhance a friction property and abrasion resistance, a coating film, which includes an amorphous matrix containing Ti as a main component, and a nanocomposites microstructure having nanocrystals containing a TiN component dispersed in the matrix, may be provided.

According to one aspect of the present disclosure for manufacturing a coating film including a novel component and a microstructure to enhance a friction property and abrasion resistance, a method of manufacturing a coating film, which includes inputting and installing a base material into a sputtering device, and forming a coating film on the base material surface by sputtering a target while nitrogen or a reaction gas containing nitrogen is input into the sputtering device, may be provided, and the coating film includes an amorphous matrix containing Ti as a main component and a nanocomposites microstructure having nanocrystals containing a TiN component dispersed in the matrix.

According to another aspect of the present disclosure for obtaining an amorphous coating film having further enhanced glass forming ability (GFA) to obtain an amorphous coating film using a Ti-rich composition with a high hardness as a matrix, a coating film, which includes an amorphous matrix containing Ti as a main component and a nanocomposites microstructure having nanocrystals containing a TiN component dispersed in the matrix, may be provided.

According to another aspect of the present disclosure for manufacturing an amorphous coating film having further enhanced GFA to obtain an amorphous coating film containing a Ti-rich composition with a high hardness as a matrix, a method of manufacturing a coating film, which includes inputting and installing a base material into a sputtering device; and forming a coating film on the base material surface by sputtering a target while nitrogen or a reaction gas containing nitrogen and a reaction gas containing Si are input into a sputtering device, may be provided, and the coating film includes a Si-containing amorphous matrix containing Ti as a main component, and a nanocomposites microstructure having nanocrystals containing a TiN component dispersed in the matrix.

According to another aspect of the present disclosure for providing process conditions for forming a coating film having a high H/E value and an excellent adhesive strength even to base materials containing various components, a method of manufacturing a coating film, which includes inputting and installing a base material into a sputtering device; and forming a quinary component coating film of Ti—Cu—Ni—Si—N on the base material surface by sputtering a target while nitrogen or a reaction gas containing nitrogen and a reaction gas containing Si are input into the sputtering device, may be provided, and the coating film includes an Si-containing amorphous matrix containing Ti as a main component, and a nanocomposites microstructure having nanocrystals containing a TiN component dispersed in the matrix.

According to one aspect of the present disclosure for providing a part having improved durability by preventing detachment of a coating film from a base material by including a buffer layer that is able to enhance an adhesive strength of the coating film between the base material and the coating film, a part including an aluminum alloy base material, a buffer layer disposed on the base material, and a coating film of Ti amorphous alloys or nanocomposites, which is formed on the buffer layer may be provided.

According to one aspect of the present disclosure for increasing a production rate by forming each unit film without a separate additional technique or a change in technique, and increasing the economic feasibility of equipment or a manufacturing process without separate expensive equipment or an additional technique, a method of manufacturing a part, which includes disposing a buffer layer on an aluminum alloy base material, and disposing a coating film of Ti amorphous alloys or nanocomposites on the buffer layer, may be provided.

According to another aspect of the present disclosure, a compressor which includes a coating film having any one of the nanocomposites microstructures may be provided.

According to still another aspect of the present disclosure, a compressor which includes a part including a coating film having any one of the nanocomposites microstructures may be provided.

### Advantageous Effects

According to the present disclosure, a coating film of the present disclosure can include amorphous Ti alloys as a matrix and a nanocomposites microstructure including nanocrystals of a TiN component, which are dispersed in the matrix. Particularly, since the matrix of the present disclosure is an amorphous matrix using ternary or quaternary Ti alloys of Ti—Cu—Ni—(Mo), thereby widening a composition with GFA, the amorphous matrix can be stably formed. Furthermore, the ternary or quaternary Ti alloys of Ti—Cu—Ni—(Mo) according to the present disclosure can form an amorphous matrix using a composition region with a high Ti ratio, thereby ensuring a higher hardness than other Ti alloys.

As a result, due to an inherent low elastic modulus of the amorphous matrix, compared with a crystalline microstructure, friction and abrasion properties can be enhanced and durability can be ensured.

Furthermore, in the present disclosure, as an amorphous matrix is provided using Si-added quaternary or quinary Ti alloys of Ti—Cu—Ni—Si—(Mo), the composition with GFA is widened up to a high-melting-point Ti-rich composition region due to Si addition, and therefore, the amorphous matrix can be more stably formed, compared with Ti amorphous matrixes in a different composition range.

Accordingly, as the quaternary or quinary Ti amorphous alloys of Ti—Cu—Ni—Si—(Mo) according to the present disclosure forms an amorphous matrix using a Ti-rich composition region, an amorphous matrix having a higher hardness, compared with other Ti amorphous alloys, can be provided.

In addition, as the coating film of the present disclosure can have an excellent adhesive strength to the matrix and can include TiN nanocrystals with a high hardness, a hardness/elastic modulus (H/E) ratio increases, compared with a material consisting of only an amorphous matrix or other conventional materials, and thus the durability of the coating film can be enhanced.

Therefore, the coating film of the present disclosure has an advantage that the possibility of detaching the coating film due to a low adhesive strength or breaking the coating film due to a low hardness or a high elastic modulus can be greatly reduced.

In addition, in a method of manufacturing a coating film of the present disclosure, by providing process conditions capable of forming a coating film with a high H/E value and an excellent adhesive strength even with base materials for various components, a manufacturing method capable of maximizing abrasion resistance, durability and an adhesive strength of the coating film can be established.

In addition, as the part according to the present disclosure includes a buffer layer that can improve an adhesive strength of the coating film between the base material and the coating film, detachment from a base material may be prevented, and thus durability of the coating film can be improved.

Furthermore, as the part according to the present disclosure increases an adhesive strength of the coating film, it allows a Ti amorphous or Ti nanocomposites coating film of the present disclosure to exhibit inherent abrasion resistance and durability, and thus the abrasion resistance and durability of the part can be improved. Accordingly, the lifetime of mechanical devices or air-conditioning devices, to which to the part of the present disclosure is applied, can be extended.

Meanwhile, in the present disclosure, the buffer layer and the coating film can be formed on a base material constituting the part by one manufacturing technique using reactive sputtering. Therefore, since respective unit films can be formed without a separate additional technique or a change in technique, a production rate can increase, and as there is no need of a separate high-priced equipment or technique, economic feasibility in equipment or a manufacturing process can increase.

Meanwhile, since the compressor of the present disclosure includes the part having the coating film, which includes the Ti amorphous matrix and the nanocomposites microstructure including TiN nanocrystals with a high hardness, the compressor also has an advantage of significantly improving friction and abrasion properties and reliability.

### DESCRIPTION OF DRAWINGS

FIG. 1 is a conceptual diagram for describing a coating film of the present disclosure, consisting of an amorphous structure and a nanocrystal structure.

FIG. 2 is a stress-strain curve for comparing a metallic glass, a metal nitride and a crystalline metal.

FIG. 3 is a Gibbs triangle representing compositions of Ti—Cu—Ni ternary alloys having glass forming ability (GFA) according to the present disclosure.

FIG. 4 shows X-ray diffraction (XRD) patterns exhibiting GFA of alloys in a composition range of Ti 75%-Cu x%-Ni y% (x+y=25).

FIG. 5 shows XRD patterns exhibiting GFA of alloys in a composition range of Ti 70%-Cu x%-Ni y% (x+y=30).

FIG. 6 shows XRD patterns exhibiting GFA of alloys in a composition range of Ti 65%-Cu 15%-Ni 20%.

FIG. 7 shows XRD patterns of quaternary alloys in which Mo is added to a Ti 65%-Cu 15%-Ni 20% alloy.

FIG. 8 shows XRD patterns of a coating film prepared by non-reactive sputtering according to the present disclosure.

FIG. 9 shows XRD patterns of a coating film prepared by reactive sputtering according to the present disclosure.

FIG. 10 shows a microstructure image of a coating film prepared by reactive sputtering according to the present disclosure, observed through transmission electron microscopy (TEM).

FIG. 11 shows the atomic radius differences and heat of mixing between components of Ti—Cu—Ni—Si quaternary alloys to be invented in the present disclosure.

FIG. 12 shows a Gibbs triangle representing a composition range for investigating GFA in Example 2 of the present disclosure based on the Ti—Cu—Ni ternary Gibbs triangle of FIG. 3.

FIG. 13 shows XRD patterns for investigating GFA of a (Ti—Cu—Ni)₉₇—Si₃ quaternary alloy in which 3% Si is added to 70% Ti-containing Ti—Cu—Ni ternary alloys.

FIG. 14 shows XRD patterns for investigating GFA of a (Ti—Cu—Ni)₉₅—Si₅ quaternary alloy in which 5% Si is added to 75% Ti-containing Ti—Cu—Ni ternary alloys.

FIG. 15 shows XRD patterns for investigating GFA of a (Ti—Cu—Ni)₉₃—Si₇ quaternary alloy in which 7% Si is added to 80% Ti-containing Ti—Cu—Ni ternary alloys.

FIG. 16 shows the summary of GFA in the examined total composition ranges of Ti—Cu—Ni—Si quaternary alloys.

FIG. 17 shows XRD pattern results of quinary alloys in which Mo is added to Ti 51%-Cu 41%-Ni 7%-Si 1% alloys. IG. 18 shows the change in XRD patterns according to the content of HMDSO (that is, Si) and an N₂ (that is, TiN) flow rate using a target of a reference composition.

FIG. 19 shows the micro hardness of a coating film according to an N₂ flow rate using a target of a reference composition.

FIG. 20 shows a result of evaluating the adhesive strength between a coating film and a base material such as spherical graphite cast iron and a 4007-series aluminum alloy.

FIG. 21 shows a result of evaluating the adhesive strength of a coating film according to a buffer layer after the buffer layer having various components or composition ranges is formed on an aluminum alloy base material and a coating film is then formed.

FIG. 22 shows a cross-sectional structure of a part consisting of an aluminum alloy base material/a CrN buffer layer/a Ti—Cu—Ni—N nanocomposites according to one embodiment of the present disclosure.

FIG. 23 shows a microstructure generated by forming a CrN buffer layer on an aluminum alloy base material, observed in a planar direction.

FIG. 24 shows the changes in hardness (H), elastic modulus (E) and H/E value of a coating film according to an N₂ flow rate and a bias voltage.

FIG. 25 shows the changes in adhesive strength and H/E value of a coating film according to the changes in power and bias voltage.

FIG. 26 shows the changes in adhesive strength and H/E value of a coating film according to the changes in N₂ and HMDSO flow rates.

FIG. 27 shows the cross-sectional microstructure and XRD pattern of coating films manufactured by reactive sputtering using a N₂ gas and a HMDSO gas by using a target of a reference composition and spherical graphite cast iron as base materials.

FIG. 28 shows the cross-sectional microstructure and XRD pattern of coating films manufactured by reactive sputtering using a N₂ gas and a HMDSO gas by using a target of a reference composition and an aluminum alloy as base materials.

FIG. 29 is a longitudinal cross-sectional view of a general example of a reciprocating compressor to which a gas bearing is applied.

FIG. 30 is a perspective view of a general example of a reciprocating compressor to which a conventional leaf spring is applied.

### MODES OF THE DISCLOSURE

Hereinafter, a coating film according to an exemplary embodiment of the present disclosure and a method of manufacturing the same will be described in further detail with reference to the accompanying drawings.

The present disclosure is not limited to embodiments disclosed below, but embodied in various forms, and the embodiments are merely provided to complete the disclosure of the present disclosure, and to fully inform the scope of the present disclosure to those of ordinary skill in the art.

In the description of embodiments of the present disclosure, detailed descriptions of known configurations or functions related thereto will be omitted when it is determined that the detailed descriptions would hinder the understanding of embodiments of the present disclosure. In addition, some exemplary embodiments of the present disclosure will be described in detail with reference to exemplary drawings. It should be noted that, when reference numerals are assigned to components of each drawing, like components are denoted by the same reference numerals, even if they are represented on other drawings. In addition, in the description of the present disclosure, detailed description of the related art will be omitted if it is determined that the gist of the present disclosure can be obscured.

In the description of a component of the present disclosure, the terms, for example, first, second, A, B, (a) and (b), may be used. These terms are only for distinguishing the component from another component, and the nature, sequence, order or number of a corresponding component is not limited by these terms. When a component is described as being “linked”, “coupled” or “connected” with another component, the component may be directly linked to or connected with the other component, but it will be understood that another component may be “interposed” between the components, or one component may be “linked”, “coupled” or “connected” with another component.

In addition, in the implementation of the present disclosure, components may be subdivided for convenience of description, but these components may be implemented in one device or module, or one component may be divided into multiple devices or modules.

Hereinafter, with reference to the accompanying drawings, a coating film including Ti amorphous alloys and nanocomposites microstructures having nanocrystals according to exemplary examples of the present disclosure, a sputtering method for forming the coating film formed of nanocompositess, and a compressor coated with the nanocompositess or including a part formed of the nanocompositess will be described in detail.

Most solid materials are aggregates of microcrystals, and each atom in the three-dimensional space has long-range translational periodicity, and located in a predetermined crystal lattice. On the other hand, liquid materials have a disordered structure without translational periodicity due to thermal vibration.

In a dictionary sense and in terms of atomic structure, an amorphous metal is a concept that contrasts with the crystalline alloys due to the fact that it is a solid having no long-range order patterns, which is a typical atomic structure of crystalline alloys, and present in a disordered state having a liquid structure.

The “amorphous” used herein refers to the case having amorphous characteristics conventionally known in the corresponding art to which the present disclosure belongs, that is, the general concept of the amorphous structure mainly forming a microstructure, and an XRD pattern of the amorphous structure shows a diffused halo shape.

Furthermore, the “amorphous” used herein also means that the structure of the composition is partially amorphous as a main phase, not losing the amorphous characteristics, as well as being 100% amorphous. Specifically, it also includes the case in which an amorphous structure is partially crystalline (or nanocrystalline), or an inter-metallic compound or silicide is partially present in the amorphous structure. Here, the nanocrystal refers to a crystal grain with a nanometer size (hundreds of nm or less) on average.

Particularly, in the present disclosure, it is intended to specifically distinguish a microstructure called a nanocomposites, which is different from the “amorphous” material. The nanocomposites of the present disclosure refers to a microstructure which includes the above-defined amorphous material as a matrix, and a nano-sized crystal grain intentionally having a desired component and/or composition range in the matrix.

Since the amorphous or nanocomposites microstructure of the present disclosure includes an amorphous material as a main component, glass forming ability is a substantially very important factor.

Generally, the glass forming ability (GFA) refers to how easily an alloy of a specific composition can be amorphized. Generally, the GFA of metals and/or alloys is highly dependent on its composition, and may be directly evaluated by calculating a critical cooling rate (hereinafter, referred to as Rc) at which an amorphous phase can be created from a continuous cooling transformation diagram or time-temperature-transformation diagram. However, in reality, it is not easy to obtain Rc by an experiment or calculation because physical properties such as melt viscosity or latent heat of fusion according to the compositions of each alloys are different.

To form an amorphous alloy through casting, which is the most common and general method, a high cooling rate, for example, which is a certain level of Rc or more, is needed. When a casting method (e.g., a mold casting method) which has a relatively low solidification rate is used, a composition range with GFA is reduced. On the other hand, a high speed solidification method such as melt spinning for solidifying an alloy with a ribbon or wire rod by dropping a melt alloy on a rotating copper roll may commonly obtain an amorphous ribbon with several tens of micrometer-thickness using a maximized cooling rate of 104 to 106 K/sec or more so that the amorphous-forming composition range is widened. Therefore, evaluation whether a specific composition has a certain level of GFA generally shows a value relative to the cooling rate of a given cooling process.

In consideration of relative characteristics of GFA as described above, the “alloy with GFA” used herein refers to an alloy that can obtain an amorphous ribbon in casting using a melt spinning method.

The coating film of the present disclosure may be applied to various mechanical parts, for example, a compressor, and more specifically, parts such as a coating film and/or an inner ring, formed on a friction region of a compressor having a gas bearing. The coating film of the present disclosure and the part to which the coating film is applied may improve durability, a low friction property, abrasion resistance and a running-in property of various mechanical parts due to the nanocomposites microstructure according to the present disclosure.

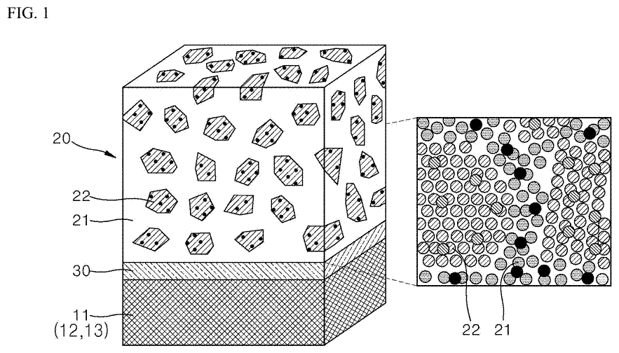

FIG. 1 is a conceptual diagram for describing a nanocomposites or coating film of the present disclosure.

The coating film of the present disclosure, shown in FIG. 1, is an example formed in a friction region between a rotating shaft and a bearing. In FIG. 1, a nanocomposites coating film 20 and a base material 11, 12 or 13 on which the coating film 20 is formed are shown. The base material 11, 12 or 13 on which the coating film 20 is coated may include all materials that are able to be used as a structural material. However, a metal is more preferable than other materials, which is due to rapid cooling caused by high thermal conductivity inherent in the metal, thereby promoting the formation of an amorphous material as a matrix of the coating film 20.

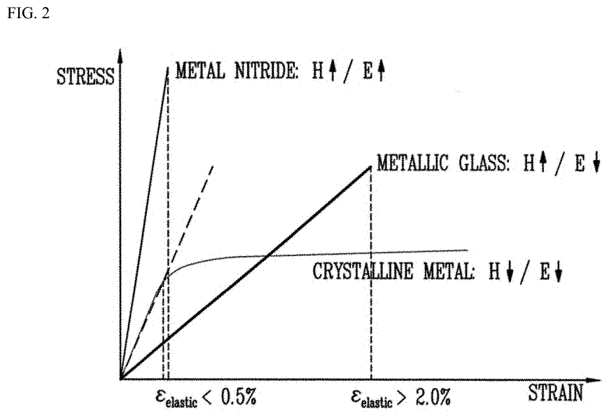

FIG. 2 is a stress-strain curve for comparing a metallic glass, a metal nitride and a crystalline metal.

Here, the stress refers to resistance generated in a material when an external force is applied to the material. The strain refers to a ratio of the deformation amount in a material and the original length of a material. A slope of the stress-strain curve corresponds to an elastic modulus.

Generally, the durability (reliability with respect to abrasion resistance) of the coating film may be evaluated as a ratio (H/E) of hardness (H) and an elastic modulus (E). When the H/E ratio is a relatively large value, there is a low possibility of being detached or broken due to the high durability of the coating film.

When an interfacial elasticity property (or mechanical property) between the base material 11, 12 and 13 and the coating film 20 is not similar to each other, due to the effect of residual stress during deformation, the coating film 20 may be easily detached from the base material 11, 12 or 13, or may be broken. The inconsistent elastic properties mean that a large difference in elastic modulus between the base material 11, 12 or 13 and the coating film 20.

Conventional coating materials generally have a high-hardness ceramic phase as a main phase, and thus have a high elastic modulus. Accordingly, since the conventional coating materials have a large difference in elastic modulus from the base material 11, 12 or 13 even when a soft crystalline phase is precipitated, they exhibit low interfacial stability despite excellent initial coating performance. As a result, the conventional coating materials do not have sufficient sustainability as they are easily detached from the base material or broken. The detachment or destruction of the coating film 20 means that the durability (reliability with respect to abrasion resistance) of the coating film 20 is low.

Generally, a metal nitride has a very high hardness. However, the metal nitride has a high elastic modulus as seen from the slope of the graph shown in FIG. 2. In addition, the metal nitride has a low elastic deformation limit of 0.5% or less. Therefore, when the metal nitride is used as a matrix of the coating film, the metal nitride may form a high-hardness coating film due to a relatively high hardness, whereas it is difficult to ensure the durability of the coating film due to a high elastic modulus.

Meanwhile, as seen from the slope of the graph shown in FIG. 2, the crystalline metal has a very low elastic modulus. In addition, the crystalline metal has a low elastic strain limit of 0.5% or less, like the metal nitride. Since the elastic strain limit of the crystalline metal is very small, it is considered that plastic deformation usually occurs from a strain of 0.2% or more (0.2% Offset yield strain). Furthermore, the hardness of the crystalline metal is a very low hardness, compared with the metal nitride. As a result, the crystalline metal may obtain a certain level of durability of the coating film due to a low elastic modulus, whereas it is difficult to form a high-hardness coating film due to a relatively low hardness.

As confirmed from the result obtained with the metal nitride and the crystalline metal, the higher the hardness, the higher the elastic modulus. Conversely, as the elastic modulus decreases, the hardness likely decreases. Therefore, it is very difficult to improve ratios of the hardness and the elastic modulus at the same time. This means that it is difficult to ensure the durability of the high-hardness coating film through a high hardness and a low elastic modulus.

However, the present disclosure may realize a high hardness and a low elastic modulus using a nanocomposites microstructure including an amorphous material and metal nitride nanocrystals.

Generally, the metallic glass has a lower hardness than the metal nitride, but a higher hardness than the crystalline metal. Here, referring to FIG. 2, the elastic modulus of the metallic glass is very low, compared with that of the crystalline metal or metal nitride. In addition, since the elastic strain limit of the metallic glass is 1.5% or more, the metallic glass has a wide elasticity limit, and therefore serves as a buffer between the coating film and a friction material. Therefore, unlike the general tendency shown in the metal material described above, the metallic glass has a high hardness, a low elastic modulus and a high elastic strain limit. Meanwhile, the metal nitride may be very effectively used in achievement of a high hardness as a reinforcing phase, not a main phase. For example, in the case of a composite in which a metal nitride is present as a reinforcing phase in a matrix with a relatively low elastic modulus, such as a crystalline metal or an amorphous material, the matrix serves to ensure durability and the metal nitride serves to ensure a high hardness, so that it is possible to ensure both of a high hardness and durability.

Accordingly, the nanocomposites microstructure in which a metal nitride is included in a metallic glass matrix in the present disclosure has a high hardness and a high H/E ratio, compared with a conventional microstructure consisting of a crystalline metal or a metal nitride, and furthermore, only an amorphous material.

As a result, the nanocomposites coating film using a metallic glass and a metal nitride has an advantage of having reliability (durability) as well as abrasion resistance caused by a high hardness of the amorphous material.

More specifically, the part including the coating film 20 in the present disclosure shown in FIG. 1 may form a composite structure consisting of an amorphous material 21 and a nanocrystalline material 22. By the way, since the coating film 20 including the amorphous material 21 of the present disclosure has a higher hardness and a lower elastic modulus than the crystalline alloys, even when a high-hardness film is formed with a metal nitride, the detachment or destruction of the coating film 20 may be minimized. Therefore, the coating film 20 of the present disclosure has a higher durability (reliability with respect to abrasion resistance) than conventional coating materials.

Hereinafter, the coating film and a method of manufacturing the same according to the present disclosure will be described with reference to various examples and experimental examples.

### EXAMPLE 1

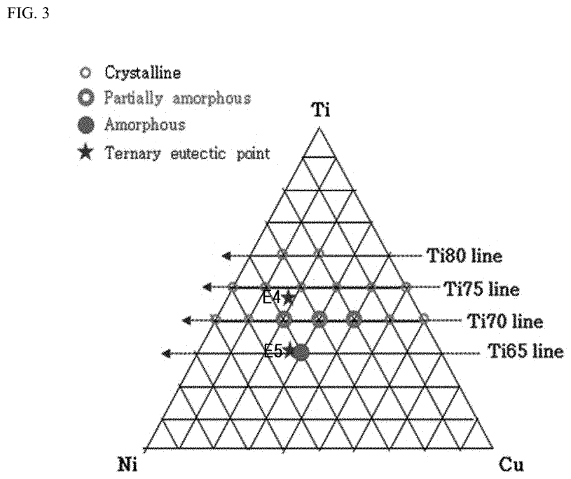

FIGS. 3 to 6 show compositions with GFA and XRD results of Ti—Cu—Ni ternary alloys serving as a matrix in the coating film of the present disclosure and having GFA.

As shown in FIG. 3, it can be seen that Ti—Cu—Ni has two ternary eutectic points.

There are two eutectic points, such as a Ti-9.1% Cu-17.7% Ni eutectic point, which is at% represented as E4 (hereinafter, all% in a composition refers to at%) and a Ti-12.9% Cu-21.8% Ni eutectic point represented as E5.

As known from the term “eutectic,” it is because the eutectic point means a temperature at which a liquid phase may be maintained until the lowest temperature in a certain alloy system. As a result, a composition near a eutectic point refers to a composition in which a liquid phase is present at the lowest temperature in terms of thermodynamics, and in terms of reaction kinetics, since supercooling occurs in nucleation, as a result, this is the most advantageous composition that can ensure GFA in Ti—Cu—Ni ternary alloys.

While there is an additional eutectic point in the Ti—Cu—Ni ternary alloys, in the present disclosure, an alloy in a Ti-rich region, which is able to obtain an effect of forming high-hardness phases as well as a low elastic modulus (E) effect caused by an amorphous alloy was invented.

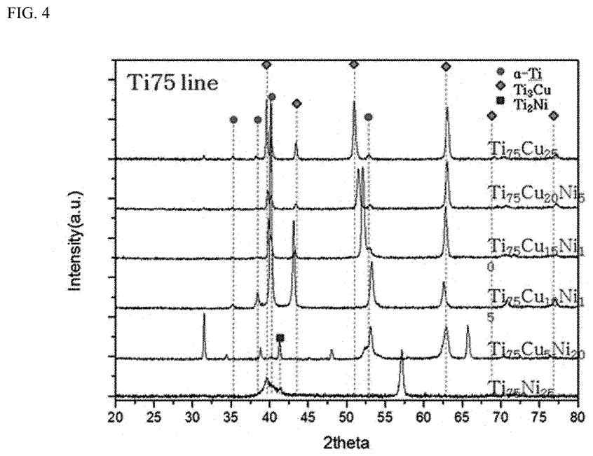

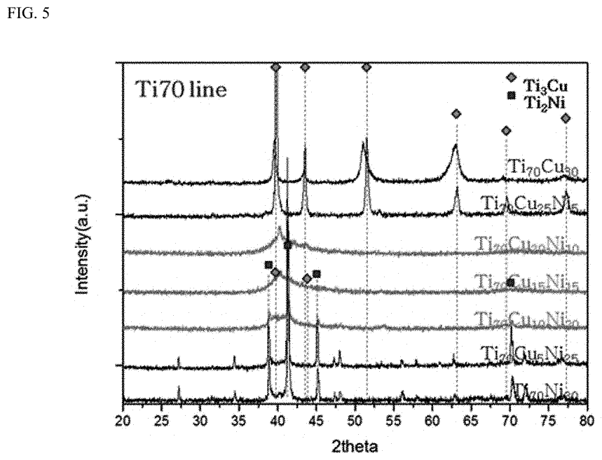

First, after a Ti content is fixed at 75%, in the Ti—Cu—Ni ternary alloys in which Cu and Ni were controlled within a 25% range, GFA was not observed in the investigated region (FIG. 4). Otherwise, it was confirmed from FIG. 5 that, in Ti—Cu—Ni ternary alloys which has a Ti content of 70% and in which Cu and Ni were controlled within the remaining 30% range, there is composition regions with GFA in the examined region.

Particularly, the XRD result can show that, in composition regions in which a Cu+Ni content is 30%, a Cu content is 20 to 10%, and an Ni content is 10 to 20%, the main phase is amorphous. Furthermore, when the Ni content increases from 10% to 20% in the composition region, a weak diffraction peak of a Ti2Ni phase is observed in the XRD result.

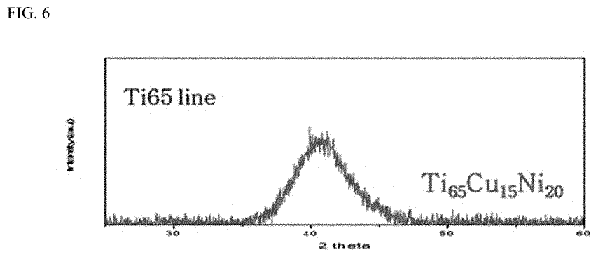

Meanwhile, the Ti—Cu—Ni ternary alloy in which a Ti content is decreased to 65% also had a composition region with GFA. Particularly, the Ti-15% Cu-20% Ni ternary alloy near the Ti—Cu—Ni ternary eutectic point also showed the same XRD peak as a different Ti—Cu—Ni ternary alloy with GFA (FIG. 6). From the above XRD result, it was confirmed that the Ti—Cu—Ni ternary alloys of the present disclosure have GFA in a composition range of Ti: 65 to 73.2%, Cu: 9.1 to 20% and Ni: 10 to 21.8%.

Meanwhile, in the present disclosure, other than the Ti—Cu—Ni ternary alloy, a Mo-added Ti—Cu—Ni—Mo quaternary alloy may also be used as an amorphous matrix of the nanocomposites microstructure of the present disclosure.

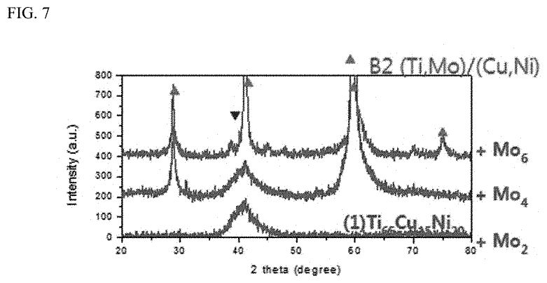

FIG. 7 shows the XRD results of quaternary alloys in which Mo is added to a Ti 65%-Cu 15%-Ni 20% alloys, represented by at% (hereinafter, referred to as %) in another disclosure invented by the inventors.

First, compared with the composition range of the entire alloy, the XRD pattern of a 2% Mo-containing (Ti 65%-Cu 15%-Ni 20%)98-Mo2 alloy (which is an alloy in which 2% Mo is added again to 98% of an alloy of a Ti 65%-Cu 15%-Ni 20% composition, and other alloys represented in the same manner below also have the same type of composition) shows a diffused halo shape, which is the typical XRD pattern of amorphous phases. The XRD result indicates that in quaternary alloys having the above composition, the entire region of the microstructure is amorphous.

On the other hand, when the Mo content is increased to 4%, the XRD peaks of crystalline B2 phases are observed, in addition to the conventional amorphous XRD pattern. This means that a composite microstructure in which an amorphous phase and a crystalline B2 phase are mixed is formed in a 4% Mo-added quaternary alloy.

When the Mo content is further increased to 6%, almost all of the halo-shape pattern, which is the unique XRD pattern of a conventional amorphous material, disappears, and there are only peaks corresponding to beta (β) Ti of a BCC lattice and crystalline B2. This means that a 6% Mo-added quaternary alloy is a crystalline alloy, not an amorphous alloy anymore.

Meanwhile, Table 1 shows results obtained by measuring a hardness value according to a Mo content by the nano-indentation of a Ti—Cu—Ni ternary alloy and a Ti—Cu—Ni—Mo quaternary alloy, which can be used as a matrix of the coating film of the present disclosure.

TABLE 1
Nano-indentation result according to Mo content

| Composition | H (GPa) |
|---|---|
| (Ti:65%-Cu:15%-Ni:20%) | 6.761 |
| (Ti:65%-Cu:15%-Ni:20%) + Mo2% | 7.517 |
| (Ti:65%-Cu:15%-Ni:20%) + Mo4% | 7.514 |
| (Ti:65%-Cu:15%-Ni:20%) + Mo6% | 8.338 |

As clearly shown in Table 1, it can be seen that the higher the Mo content, the higher the hardness of the amorphous matrix. The increase in hardness level is due to an increase in fraction of the B2 phase in the matrix according to the increased Mo content.

In addition, Mo is known to generally have self-lubricity. Accordingly, the addition of Mo has an advantage of achieving an improved lubricating property as well as the increased hardness in a certain content range.

Therefore, the Ti—Cu—Ni—Mo quaternary alloys, as the amorphous matrix of the nanocomposites microstructure of the present disclosure, having a composition range of Ti: 51 to 65%, Cu: 15 to 41%, Ni: 7 to 20%, Mo: 1 to 5%, which can maintain an amorphous phase and increase a hardness level was selected.

Meanwhile, the nanocomposites microstructure of the present disclosure includes a nanocrystalline metal nitride as a reinforcing phase, in addition to an amorphous phase, and more particularly, TiN, as a matrix.

Here, the TiN nanocrystals as a reinforcing material may be formed by various methods. For example, a physicochemical deposition such as sputtering or chemical vapor deposition may be used.

Generally, to deposit a non-conductor such as TiN on a substrate by sputtering, first, high-frequency, that is, radio frequency (RF)-type sputtering should be used. Such an RF method has disadvantages of difficulty in manufacturing a non-conductor target that is required for deposition and being expensive, as well as the need of equipment more expensive than DC sputtering equipment used for sputtering of a conductor such as a metal. Moreover, in the present disclosure, since the Ti amorphous alloy as a matrix uses DC sputtering, the use of RF sputtering, not DC sputtering, is disadvantageous in a process.

Therefore, when the TiN nanocrystal is deposited like the Ti amorphous alloy, which is the matrix, using DC sputtering, it may increase productivity of the process, and may also be advantageous for a nanocomposites microstructure, resulting in improvement in properties of the coating film. In the reactive sputtering process, DC sputtering may be used, and thus the above-described excellent effects may be expected.

In addition, in the findings that the amorphous alloy, as the matrix of the coating film of the present disclosure, can be deposited by sputtering and the TiN nanocrystals as a reinforcing material of the present disclosure have to be dispersed in the matrix, rather than coated on the matrix, it is more preferable that the TiN nanocrystals as the reinforcing material of the present disclosure use reactive sputtering.

The reactive sputtering is a method of sputtering by injecting a gas of a desired component required for a reaction in the DC sputtering method. For example, oxygen is added for the deposition of an oxide, and a nitrogen gas or a reaction gas (e.g., NH₃) containing nitrogen is added for the deposition of a nitride, thereby forming an oxide film, a nitride film, a carbide film or a film of a mixed composition with desired components and/or composition range by the reaction of a target metal and the reaction gas.

The stoichiometric ratio between components of the film formed as above may be usually controlled with an amount of a reaction gas. More specifically, in each line of a reaction gas for common sputtering equipment, a mass flow controller (MFC) is installed, and the desired components and/or composition range can be controlled by controlling the MFC.

Hereinafter, particular aspects of the present disclosure will be described with reference to experimental examples.

### EXPERIMENTAL EXAMPLE 1

First, an alloy of a Ti:72%, Cu:12%, Ni:16% composition was prepared as a target, and then a coating film was formed by sputtering.

In the present disclosure, Ti—Cu—Ni—(Mo) ternary or quaternary alloys of compositions known to have GFA described above was dissolved by vacuum arc melting, and ribbon or foil-type amorphous alloys were obtained by melt spinning. Subsequently, multiple ribbons were stacked, and then heat-compressed in a temperature range higher than the crystallization-initiating temperature and lower than a melting temperature of the composition of the ribbons, thereby obtaining a sputtering target having a crystalline phase.

Meanwhile, by another method, a crystalline sputtering target may be prepared using amorphous alloys powder having Ti—Cu—Ni—(Mo) ternary or quaternary alloys composition. In this case, an aggregate of amorphous alloys powders prepared by atomization may be bound by high-temperature sintering or high-temperature pressure sintering, thereby preparing a crystalline sputtering target. In this case, the sintering temperature is in a range higher than a crystallization-initiating temperature and a melting temperature of the composition of the alloys powders.

As specific sputtering conditions, both non-reactive sputtering for forming a thin coating film in an Ar atmosphere, corresponding to Comparative Example, and reactive sputtering for forming a coating film in a mixed gas atmosphere containing Ar and N₂, corresponding to Experimental Example, were performed.

In both of the comparative example and the experimental example, the sputtering power was 2.5 kW, a bias voltage for acceleration was 78V, and a substrate temperature was maintained at 150° C.

Meanwhile, a buffer layer was used on a base material of spherical graphite cast iron or aluminum, which was used as a substrate when needed. Generally, the buffer layer is used to perform a function of improving an adhesive strength between the coating film and the base material, perform a function of relieving stress between the base material and the coating film, and improve other surface characteristics. However, the present disclosure does not necessarily include a buffer layer, and the buffer layer according to the present disclosure does not necessarily perform the above-described functions nor the buffer layer has to perform the above-described functions.

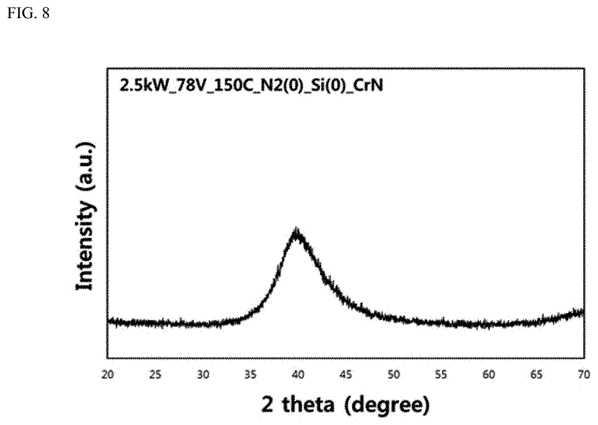

FIG. 8 shows an XRD analysis result of a coating film manufactured by non-reactive sputtering according to a comparative example of the present disclosure. The halo-shaped XRD pattern shows that the coating film manufactured by non-reactive sputtering as the comparative example of the present disclosure, as shown in FIG. 8, is entirely formed of an amorphous microstructure.

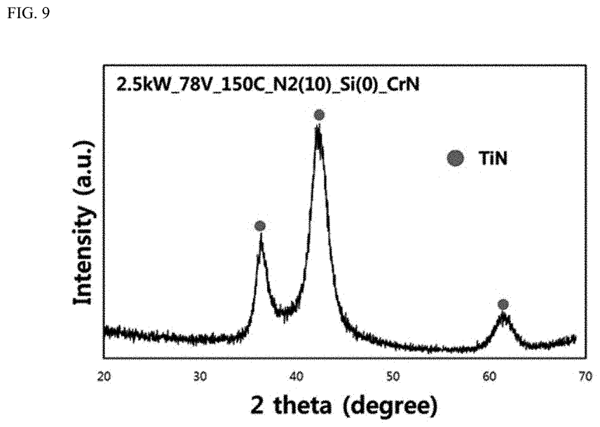

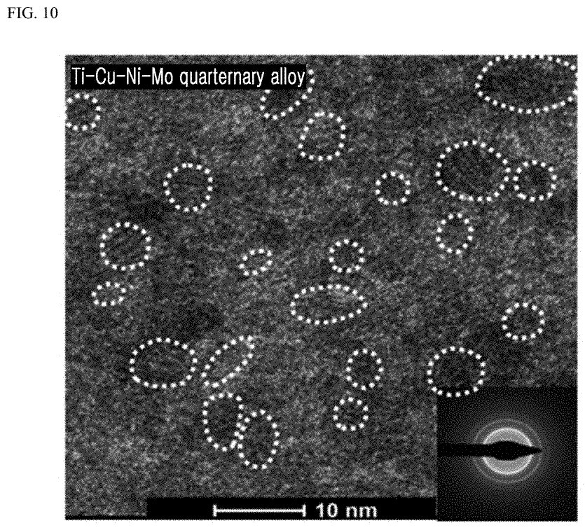

In addition, FIGS. 9 and 10 show an XRD analysis result of a coating film manufactured by reactive sputtering, which is Experimental Example 1 of the present disclosure, and microstructure images observed through transmission electron microscopy (TEM).

In Experimental Example 1 of the present disclosure, unlike the comparative example of FIG. 8, the sharp peak of a crystalline phase was observed in the XRD pattern of FIG. 9. As a result of analysis, it was found that all of the peaks correspond to the diffraction peak of a TiN crystal.

The result of XRD analysis in FIG. 9 coincides well with the microstructure image observed through TEM, shown in FIG. 10.

First, FIG. 10 shows that there are a region serving as a matrix and nano-sized second phases indicated by a dotted line. Here, as shown in FIG. 10, a partial ring pattern, as well as a diffuse pattern, may be observed on a selected area diffraction pattern (SADP), indicating that the nano-sized second phases as well as the amorphous matrix are present. It was able to be confirmed by the component analysis along with the ring pattern analysis that the coating layer described in Experimental Example 1 of the present disclosure has an amorphous matrix and a microstructure in which several nm-sized TiN nanocrystals having a TiN composition are dispersed in the matrix.

Evaluation of mechanical properties in Experimental Example 1 and the comparative example of the present disclosure is summarized in Table 2 below.

Here, the adhesive strength of the coating film was measured on the coating surface using a JLST022 tester according to ISO 20502 (measurement of adhesive strength of coating layer using scratch test) using a scratch tester. In addition, a hardness and an elastic modulus were measured on the coating surface using a HM2000 tester (FISCHERSCOPE) according to ISO 14577 (instrumented indentation test method for metallic and non-metallic coatings) using a nano-indenter.

Also as shown in Table 2, in the case of Experimental Example 1 of the present disclosure, compared with the comparative example, the adhesive strength and the hardness greatly increase, and the elastic modulus is maintained at almost the same level. As a result, in the case of Experimental Example 1 of the present disclosure, compared with the comparative example, an adhesive strength and a H/E value, which is the most important property required for a lubricating membrane, were greatly improved.

TABLE 2
Result of evaluating mechanical property according to sputtering

| | | | | Hardness/ |
|---|---|---|---|---|
| | Adhesive | Hard- | Elastic | Elastic |
| | strength | ness | modulus | modulus |
| Composition | (N) | (GPa) | (GPa) | (H/E) |
| (Ti:72%-Cu:12%-Ni:16%)- | 1.2 | 7.7 | 147 | 0.052 |
| nonreactive | | | | |
| (Ti:72%-Cu:12%-Ni:16%)- | 12.9 | 13.2 | 159 | 0.083 |
| reactive | | | | |

The noticeable improvement in mechanical properties in Experimental Example 1 of the present disclosure is closely related with a microstructure. In the present disclosure, Ti present in the Ti alloys target serves as a precursor for forming a TiN nanocrystal in the amorphous alloys, which are the matrix, by reactive sputtering. As a result, a coating film that includes a microstructure, a so-called nanocomposites, including the nanocrystal containing the TiN component finely dispersed in the amorphous matrix is formed. The nanocomposites microstructure is considered to impart low friction, high hardness and an excellent adhesive strength to the coating film due to a synergistic effect between a low elastic modulus, which is inherent in an amorphous material, and a high hardness, which is inherent in TiN, compared with other conventional coating films having a crystalline or amorphous microstructure.

### EXAMPLE 2

Example 1 showed that the hardness of the coating film is changed according to a component and/or a composition range even in the same amorphous microstructure constituting the coating film. In another example, in Ti alloys, particularly, Ti—Cu—Ni—(Mn) ternary or quaternary amorphous alloys, it is known that a Ti-rich composition region with a high Ti content has the highest hardness. This is because, as the Ti content is higher, Ti easily forms an inter-metallic compound or silicide, which is advantageous for realizing a super-high hardness property, with other alloy elements.

However, even though the coating film has a high hardness, due to the mismatch in interfacial elastic property with the base material, the coating film may be broken or detached. Therefore, for compatibility of the elastic properties of the base material and the coating film, it is very important that the amorphous microstructure remains as the matrix of the coating film.

Since the Ti alloys are also usually formed as crystalline alloys using a general composition and preparation method, similar to common metals, the composition with GFA has a narrow composition range. However, the excessively narrow composition range may not only have sufficient GFA, but also has limitations in improving various properties changed according to the composition.

On the other hand, since the Ti-rich composition region has a higher melting point than a Ti-lean composition range due to the high Ti content, and thus is difficult to have GFA, a crystalline matrix, that is, _{R} Ti, is usually obtained by melt spinning. Therefore, in the Ti—Cu—Ni—(Mo) ternary or quaternary amorphous alloys, it is very important in practice that GFA in the Ti-rich composition region is improved.

Accordingly, in Example 2 of the present disclosure, a coating film which maintains GFA of the matrix in the wide Ti-rich composition range region, and simultaneously exhibits a high hardness and a low elastic modulus was developed.

More specifically, quaternary or quinary alloys to which an alloy element, Si, capable of decreasing a melting point to improve the matrix GFA in the Ti-rich composition region, is added was designed based on the Ti—Cu—Ni—(Mo) ternary or quaternary alloys.

Then, a nanocomposites coating film having a high hardness without a significant increase in elastic modulus was invented by forming a microstructure that includes a nanocrystal including a TiN component finely dispersed in the amorphous matrix having the Si-added alloys composition.

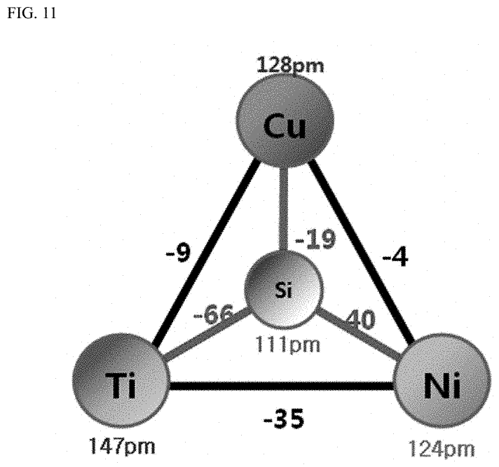

FIG. 11 shows the atomic radius differences and heat of mixing between components of Ti—Cu—Ni—Si quaternary alloys to be invented in the present disclosure. As shown in FIG. 11, it can be seen that the atomic radius of Si has an at least 12% or more difference from the atomic radii of Ti, Cu and Ni. In addition, it was confirmed that heats of mixing between Si and Ti and Cu and Ni are negative with absolute values, which are higher than that between respective components of the Ti—Cu—Ni ternary amorphous alloys according to another disclosure by the inventors.

Due to the properties of Si, the inventors selected Si as a fourth element to ensure GFA in the Ti-rich composition region of the Ti—Cu—Ni ternary amorphous alloys.

However, the optimal Si content that can ensure GFA is not a factor that can be easily predicted or elicited by those of ordinary skill in the art. This is because, since each metal has different relative lattice stability, the degree of a melting point drop with respect to the Si content when Si was added to Ti, Cu and Ni varies according to each element, and the composition for forming a silicide is also different depending on Ti, Cu or Ni.

In addition, while the increase in Si content before the eutectic point composition is advantageous in terms of decreasing the melting point of the alloys, there is another side effect in that the higher the Si content, the higher the silicide fraction.

Accordingly, it is very important to deduce an Si content that can reduce a melting point and inhibit excessive precipitation of the silicide.

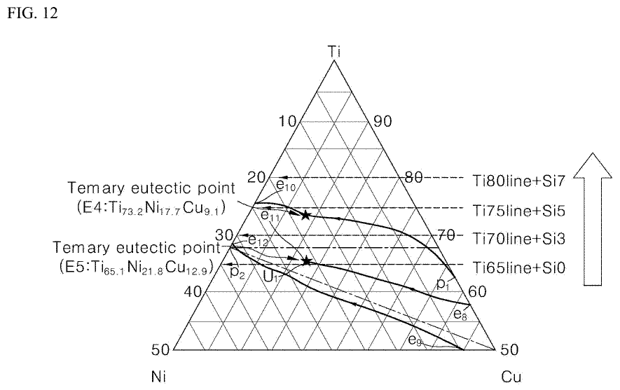

FIG. 12 shows a Gibbs triangle representing a composition range for investigating GFA in Example 2 of the present disclosure based on the Ti—Cu—Ni ternary Gibbs triangle of FIG. 3. As shown in FIG. 12, in Example 2 of the present disclosure, GFA of the Ti—Cu—Ni—Si—(Mo) quaternary or quinary alloys was investigated in a wide range from a Ti-lean composition region which has a smaller Ti content than the E5 composition to a Ti-rich composition region which has a larger Ti content than the E4 composition.

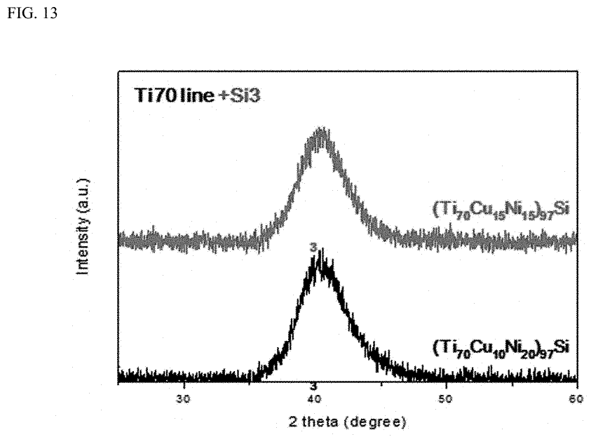

FIGS. 5 and 13 shows the XRD results obtained by examining GFA of Ti—Cu—Ni ternary alloys and Ti—Cu—Ni—Si quaternary alloys, which contain 70% Ti, respectively.

First, as described in Example 1, the XRD result can show that the Ti—Cu—Ni ternary alloys have an amorphous phase as a main phase in a composition region in which the Cu+Ni content is 30%, the Cu content is 10 to 20%, and the Ni content is 10 to 20% (FIG. 5). Furthermore, when the Ni content in the composition region increases from 10% to 20%, a weak diffraction peak of a Ti2Ni phase is observed through XRD analysis. This means that the Ti—Cu 10%-Ni 20% ternary alloys have a composite microstructure co-existing with a Ti2Ni phase in the amorphous matrix.

On the other hand, it was confirmed that the Ti—Cu—Ni—Si quaternary alloys in which 3% Si is added to the Ti—Cu—Ni ternary alloys also has GFA in a composition region in which the Cu+Ni content is 30%, the Cu content is 10 to 20%, and the Ni content is 10 to 20% (FIG. 13). However, the Ti-10% Cu-20% Ni ternary alloys have a microstructure partially having a crystalline phase, that is, a Ti2Ni phase (FIG. 5), whereas FIG. 13 shows that, in the (Ti—Cu 10%-Ni 20%)₉₇Si₃ quaternary alloy, only an almost pure amorphous phase that does not substantially include a crystalline Ti2Ni phase is formed. This result can directly mean that the addition of 3% Si significantly enhances the GFA of the Ti—Cu—Ni—Si quaternary alloys.

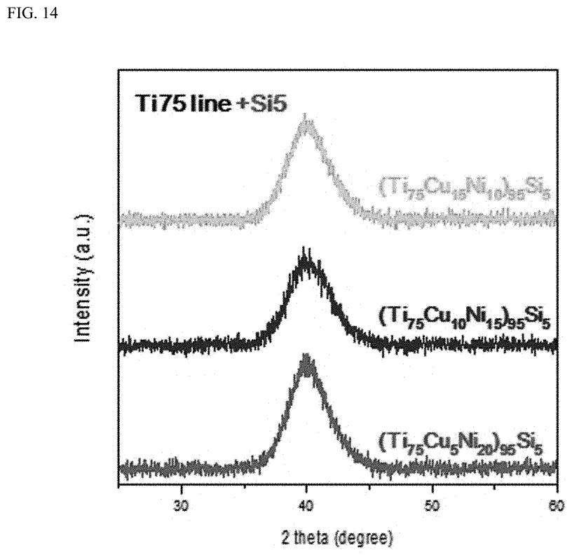

FIGS. 4 and 14 show the XRD results obtained by examining GFA of Ti—Cu—Ni ternary alloys and Ti—Cu—Ni—Si quaternary alloys, each of which contains 75% Ti, respectively.

First, as shown in Example 1, it was confirmed that the Ti—Cu—Ni ternary alloys has no GFA in the composition region of the examined entire ternary alloy containing 75% Ti. This means that Ti—Cu—Ni ternary alloys containing more Ti than the E4 composition substantially have no GFA.

However, it was confirmed that Ti—Cu—Ni—Si quaternary alloys in which 5% Si is added to the Ti—Cu—Ni ternary alloys have GFA in a wide composition region (however, the composition satisfying Ti+Cu+Ni=95%) in which the Cu+Ni content is 25%, the Cu content is 5 to 15%, and the Ni content is 10 to 20%, unlike the ternary alloys (FIG. 14). In addition, it was examined whether these quaternary alloys are present only in an almost pure amorphous phase that does not substantially include an inter-metallic compound or silicide.

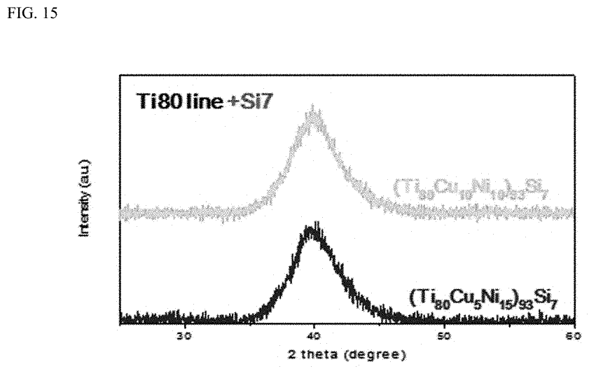

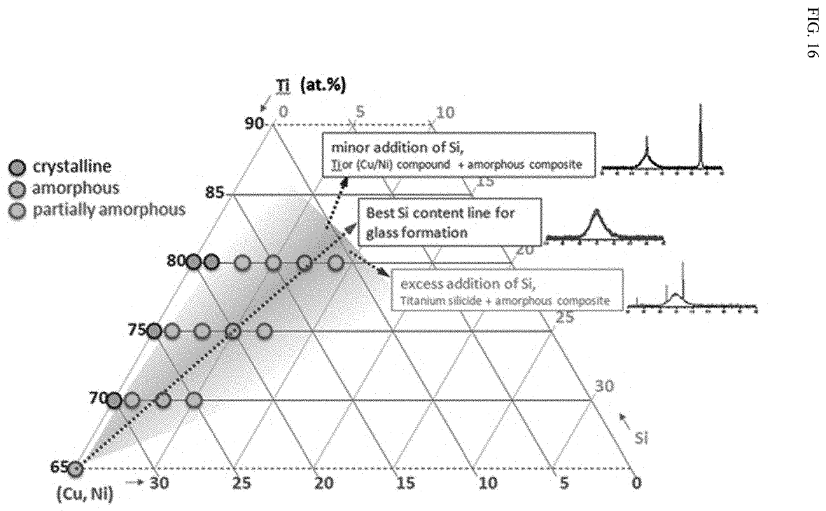

FIG. 15 shows the XRD result examining GFA of an 80% Ti-containing Ti—Cu—Ni—Si quaternary alloy.

From the experimental results, the inventors confirmed that Ti—Cu—Ni ternary alloys in which 80% or more Ti is added have no GFA in the examined total composition region. However, it was confirmed that Si-containing T-Cu—Ni—Si quaternary alloys have GFA in a composition region (however, the composition satisfying Ti+Cu+Ni=93%) in which the Cu+Ni content is 20%, the Cu content is 5 to 10%, and the Ni content is 10 to 15%, unlike the ternary alloys. In addition, it was whether these quaternary alloys are present only in an almost pure amorphous phase that does not substantially include an inter-metallic compound or silicide.

FIG. 16 shows the summary of GFA in the examined total composition ranges of Ti—Cu—Ni—Si quaternary alloys. First, from the XRD pattern experimental result, it can be seen that the composition region on the dotted arrow extending from the bottom left to the top right in FIG. 16 has GFA and a microstructure almost all of which is formed in an amorphous phase. However, the XRD pattern result shows that the shaded composition region on the left side of the arrow has GFA, has an amorphous phase as a main phase of the microstructure, and contains an inter-metallic compound in a part thereof. On the other hand, the shaded composition region on the right side of the arrow represents a composition region which has GFA, has an amorphous phase as a main phase of the microstructure, and contains silicide in a part thereof.

From the above-described experimental results, it was confirmed that Ti—Cu—Ni—Si quaternary alloys having a composition range having Ti: 59.2 to 80%, Cu: 4.6 to 20%, Ni: 4.6 to 25% and Si: 9% or less (excluding 0) stably have GFA.

In addition, in the present disclosure, other than the Ti—Cu—Ni—Si quaternary alloys, Mo-added Ti—Cu—Ni—Si—Mo quinary alloys may also be used as an amorphous matrix of the nanocomposites microstructure of the present disclosure.

As shown in Example 1, the Mo addition induces additional formation of the B2 phase having an ultra-high elastic strain that facilitates reversible phase change at room temperature as a second phase in a Ti amorphous alloy matrix. The B2 phase reversibly absorbs the stress and/or strain at the interface where friction occurs from an elastic region, and is able to improve friction and abrasion properties and ensure the dimension stability of a part. In addition, due to the ultra-high elastic strain of the B2 phase, toughness may be improved so that the reliability of a part may also be improved. However, to avoid degradation of GFA of the Ti alloys, which are the matrix, by the formation of the second phase such as the B2 phase, the Mo-added Ti—Cu—Ni—Si—Mo quinary alloys preferably have a composition range in which the Ti content is lower than that of the Ti—Cu—Ni—Si quaternary alloys.

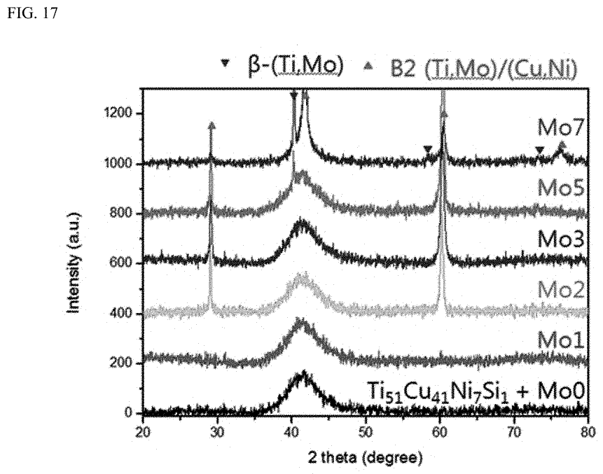

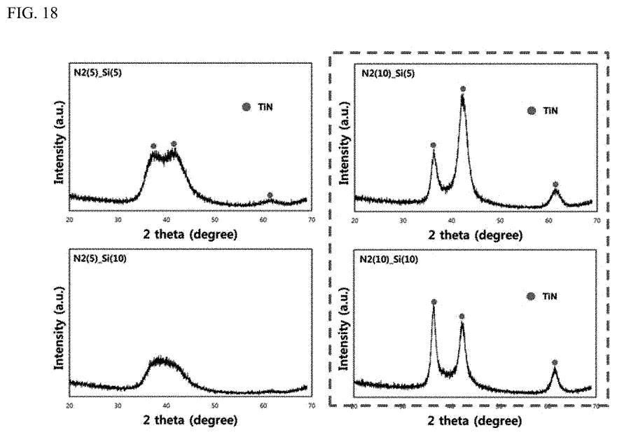

FIG. 17 shows the XRD result of quinary alloys in which Mo is added to a 51% Ti-41% Cu-7% Ni-1% Si alloys.

The quinary alloys in which Mo is added to an Si-added 51% Ti-41% Cu-7% Ni-1% Si alloys which is further reduced in Ti content and improved in GFA was expected to have more stable GFA due to the following reason, in addition to the reason in which the Ti content is lower and thus the melting point is lower, compared with the above-described quaternary alloy.

First, XRD patterns of a Mo-free 51% Ti-41% Cu-7% Ni-1% Si alloy and a 1% Mo-added (51% Ti-41% Cu-7% Ni-1% Si alloy)₉₉Mo₁ alloy show a diffused halo shape, which is the typical XRD pattern of an amorphous phase. These XRD results show that all or almost all of a microstructure (a tiny B2 peak is observed in the 1% Mo-added alloy) of a quaternary or quinary alloy of the above-described composition is amorphous.

On the other hand, when the Mo content is increased to 2%, XRD peaks of crystalline B2 phases are observed as well as the conventional amorphous XRD pattern. This indicates that a composite microstructure in which amorphous phases and crystalline B2 phases are mixed is formed in a (51% Ti-41% Cu-7% Ni-1% Si alloy)₉₈Mo₂ alloy. In addition, the XRD result of FIG. 17 shows that the composite structure in which crystalline B2 phases are mixed with the amorphous matrix or the main phase is maintained until a composition range in which the Mo content is 5%.

Meanwhile, when the Mo content is increased to 7%, the halo-shaped XRD pattern, which is inherent in the conventional amorphous phase almost disappears, and only peaks corresponding to β-Ti of the BCC lattice and crystalline B2 are present. This indicates that a (51% Ti-41% Cu-7% Ni-1% Si alloy)₉₃Mo₇ alloy is a crystalline alloy, not an amorphous alloy anymore.

From the above experimental results, it was confirmed that Ti—Cu—Ni—Si-Mo quinary alloys having a composition range of Ti: 48.5 to 65%, Cu: 14.3 to 41%, Ni: 6.7 to 20%, Si: 1% or less (excluding 0) and Mo: 1 to 5% has not only GFA, but also stably has a crystalline B2 phase as a second phase.

However, as in Example 1 described above, the nanocomposites microstructure of Example 2 of the present disclosure may include a nanocrystalline metal nitride, and more specifically, TiN as a reinforcing phase, in addition to the amorphous phase as a matrix.

Here, the TiN nanocrystal as a reinforcing material may be formed by various methods. For example, physicochemical deposition such as sputtering or chemical vapor deposition may be used. However, for the same reasons as in Example 1, in Example 2 of the present disclosure, a reactive sputtering process used in Example 1 was used.

Meanwhile, the addition of Si to the Ti amorphous matrix constituting the coating film in Example 2 of the present disclosure may also be performed by vapor deposition at the outside of the coating film. As a specific example, Si is more preferably added to the coating film in the form of a Si-containing gas in a reactive sputtering process, rather than physicochemical deposition or chemical vapor deposition. As a specific and non-limiting example of the Si-containing gas, a volatile organic silicon compound type such as hexamethyldisiloxane (HMDSO, O[Si(CH₃)₃]₂) may be used as a Si source supplied to the coating film.

Specific aspects of Example 2 of the present disclosure will be described with reference to the following experimental examples.

### EXPERIMENTAL EXAMPLE 2

In Experimental Example 2 of the present disclosure, first, a target was prepared using an alloy of a Ti: 72%, Cu: 12%, Ni: 16% composition as a reference, and then a coating film was formed by sputtering.

As rough sputtering conditions, both of the non-reactive sputtering that forms a thin coating film in an Ar atmosphere, corresponding to the comparative example, and the reactive sputtering that forms a coating film in a mixed gas atmosphere containing Ar, HMDSO and N₂, corresponding to the Example were performed.

Specific conditions for manufacturing a coating film and a method of evaluating a property in Experimental Example 2 of the present disclosure are the same as used in Experimental Example 1.

Table 3 shows the summary of mechanical property evaluation results according to an Si content (HMDSO gas flow rate) in the Si-containing coating film in Experimental Example 2 of the present disclosure.

TABLE 3
Result of evaluating mechanical properties of coating film according to Si
content

| | | | | Elastic | |
|---|---|---|---|---|---|
| | HMDSO | Adhesive | Hardness | modulus | Hardness/Elastic |
| Target composition | (sccm) | strength (N) | (GPa) | (GPa) | modulus (H/E) |
| Ti:72%-Cu:12%-Ni:16% | 0 | 2.5 | 6.2 | 133 | 0.047 |
| Ti:72%-Cu:12%-Ni:16% | 10 | 22.7 | 18.4 | 218 | 0.084 |
| Ti:72%-Cu:12%-Ni:16% | 20 | 2.1 | 10.4 | 148 | 0.070 |
| Ti:72%-Cu:12%-Ni:16% | 30 | 10.6 | 7.4 | 113 | 0.065 |

Table 3 shows the XRD analysis result of the Si-free coating film (HMDSO gas flow rate is 0 sccm) prepared by non-reactive sputtering as Comparative Example in Experimental Example 1 described above. The halo-shaped XRD pattern can show that the coating film prepared by non-reactive sputtering as the comparative example of the present disclosure is entirely formed with an amorphous microstructure as shown in FIG. 8.

As shown in Table 3, first, when Si is added to the coating film, it can be seen that a H/E value is basically significantly increased regardless of an added amount, compared with when Si is not added. However, the H/E improvement effect is predicted to have the maximum amount of HMDSO between 0 and 20 sccm.

FIG. 18 shows the change in XRD pattern according to an HMDSO (that is, Si) content and an N₂ (that is, TiN) flow rate using a target of the reference composition.

As specific film formation conditions for coating film formation in FIG. 18, acceleration was performed using a bias voltage of 78V and a sputtering power of 2.5 kW, and a substrate temperature of a spherical graphite cast iron material was maintained at 150° C.

First, as shown in the XRD patterns on the left side of FIG. 18, when the N₂ amount is 5 sccm, it can be seen that there is little or no TiN in the coating film. This means that almost all of microstructures in coating films under these conditions are formed in amorphous phase of an Si-containing Ti alloys. In addition, in this case, when the Si content is increased from 5 sccm to 10 sccm, TiN is not present in the coating film, which is due to increased GFA of the Ti alloys according to an increased Si content.

On the other hand, as shown in the XRD patterns on the right side of FIG. 18, when the N₂ flow rate is increased to 10 sccm, in all cases, TiN is stably formed in the amorphous matrix in the coating film.

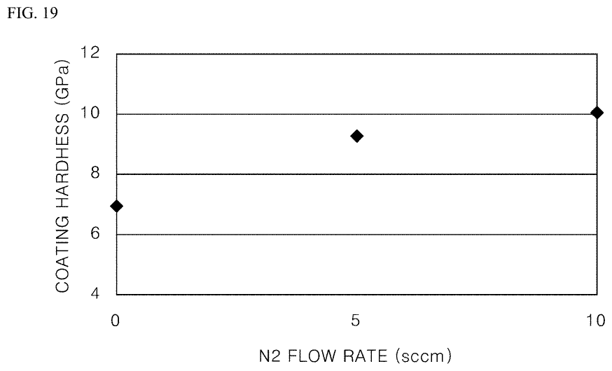

FIG. 19 shows the microhardness of a coating film according to an N₂ flow rate using a target of a reference composition.

As seen from FIG. 19, as the N₂ flow rate increases, the hardness of the coating film increases. This is because the fraction of the TiN crystals having a higher hardness than the Ti amorphous matrix is increased according to an increased N₂ injection amount.

### EXAMPLE 3

In the present disclosure, based on the results of Examples 1 and 2 and Experimental Examples 1 and 2, various experimental examples were evaluated to improve the adhesive strength of coating films in the examples and experimental examples according to the type of base material.

Particularly, the adhesive strength of the coating layer according to a base material was evaluated through measurement of an adhesive strength of the coating film according to the type of base material. Accordingly, it was determined whether a buffer layer for ensuring the adhesive strength of the coating layer according to a base material should be included.

Furthermore, when a buffer layer for ensuring the adhesive strength of a coating layer with a base material is applied, the best buffer layer was selected through evaluation of the adhesive strength of a coating layer according to the type of buffer layer.

In addition, in the present disclosure, process conditions for the best coating film according to various process conditions were established to form a coating film and a buffer layer by controlling a power, a bias voltage and a flow rate of each gas.

Various experimental examples below will be described in detail with reference to Example 3.

### EXPERIMENTAL EXAMPLE 3

In Experimental Example 3 of the present disclosure, an adhesive strength of the coating film per base material, that is, a substrate, was evaluated. In Experimental Example 3, as in the above-described Experimental Examples, a target was prepared using an alloy of a Ti: 72%, Cu: 12%, Ni: 16% composition as a reference composition, and then a coating film was formed by sputtering.

However, specific reactive sputtering conditions for forming a coating film in Experimental Example 3 are as follows.

The inside of the chamber in which a base material was disposed consisted of a vacuum of 5*10⁻⁶ to 5*10⁻⁷ torr, and a temperature of the base material, which is a substrate, was maintained at 100 to 300 ° C. under a sputtering power of 2 to 3 kW and a bias voltage of −75 to −150V while the flow rate of nitrogen was changed to 0 to 30 sccm in a mixed gas atmosphere of 1*10⁻³ to 10*10⁻³ torr Ar and nitrogen (N₂).

Meanwhile, as a substrate, a base material of spherical graphite cast iron or aluminum was used, and the coating film was directly formed on the base material without a buffer layer.

The substrate (i.e., the base material) of the present disclosure is not necessarily limited to that described above. For example, other than special cast iron such as spherical graphite cast iron, Fe-based metals, for example, all of common steel or ordinary cast iron (e.g., GC100), fine cast iron (e.g., GC250), and alloy cast iron can be used. Moreover, in the case of an aluminum alloy, not only the 4000 series, but also the 2000 series and the 9000 series can be applied.

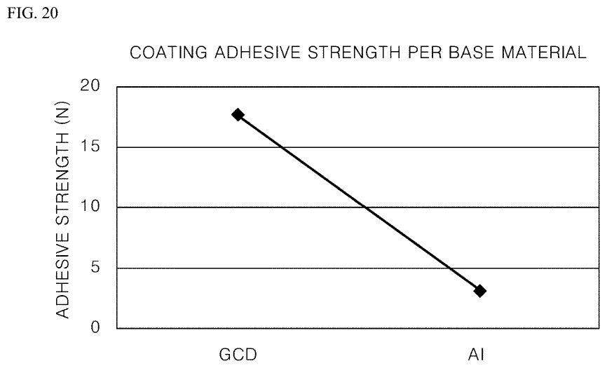

FIG. 20 shows evaluation of adhesive strength between a coating membrane and a base material such as spherical graphite cast iron and a 4007-series aluminum alloy.

As shown in FIG. 20, when the base material is spherical graphite cast iron, an adhesive strength was measured to be approximately 18N. The above-mentioned level of adhesive strength is higher than 10N, which is a common minimal requirement, and satisfies 15N, which is a preferable level.

On the other hand, when the base material is an aluminum alloy, an adhesive strength was measured to be approximately 3N, and thus, it was found that a coating film having excellent abrasion resistance and durability cannot perform an inherent function on the aluminum alloy base material.

From the result obtained from Experimental Example 3, it can be seen that the coating film of the present disclosure performs its functions without a separate buffer layer when the base material is an Fe matrix metal such as spherical graphite cast iron, but it needs a buffer layer between a coating layer and the base material when the base material is an aluminum alloy.

### EXPERIMENTAL EXAMPLE 4

In Experimental Example 4 of the present disclosure, an adhesive strength of the coating film according to a buffer layer was evaluated. In Experimental Example 4, as in the above experimental examples, a target was prepared using an alloy of Ti: 72%, Cu: 12%, Ni: 16% composition as a reference composition, and a coating film was then formed by sputtering.

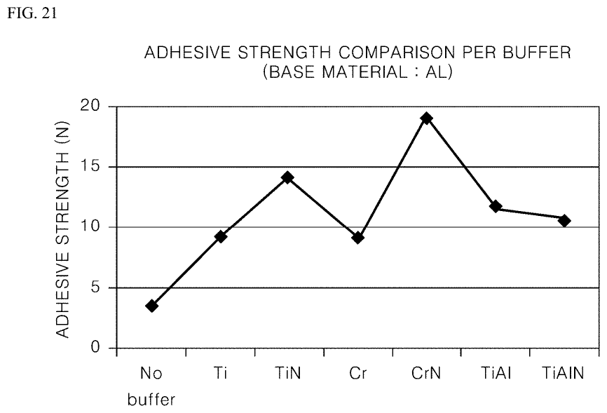

In Experimental Example 4, as shown in FIG. 21, using a 4007-series aluminum alloy base material as a substrate, buffer layers having various components or composition ranges were formed, and after a coating film was formed, the adhesive strength of the coating film was evaluated.

Generally, the buffer layer is used to perform a function of improving the adhesive strength between the coating film and the base material or relieving stress between the base material and the coating film, or to improve other surface properties.

In FIG. 21, in other words, conditions for forming the coating film in Experimental Example 4 are the same as those used in Examples 1 to 3, and thus descriptions will be omitted.

However, various buffer layers shown in FIG. 21 used a multi-sputtering process. First, a metal target for a buffer layer having different components and composition ranges from those of the target of the reference composition in Example 1 was prepared to form a coating film and installed in a chamber, and then a buffer layer having a desired component and a composition range and a coating film were formed using a shutter between the base material as a substrate and the target.

Specifically, in the case of a TiAl buffer layer, non-reactive sputtering was performed for forming a TiAl target having a desired composition, creating a vacuum of 5*10⁻⁶ to 5*10⁻⁷ torr in the chamber in which the base material is disposed, and forming a buffer layer while the temperature of the base material as the substrate was maintained at 100 to 300 ° C. in a 1*10⁻³ to 10*10⁻³ torr Ar gas atmosphere under conditions including a sputtering power of 2 to 3 kW and a bias voltage of −75 to −150V.

In the other hand, a buffer layer having a TiAlN component was formed by forming a TiAl target of the same composition as the TiAl buffer layer, creating a vacuum of 5*10⁻⁶ to 5*10⁻⁷ torr in the chamber in which the base material is disposed, and changing the flow rate of nitrogen to 0 to 30 sccm in a mixed gas atmosphere of 1*10⁻³ to 10*10⁻³ torr Ar and nitrogen (N₂). Here, a sputtering powder was maintained at 2 to 3 kW, and the buffer layer was formed by reactive sputtering under conditions including a bias voltage of −75 to −150V and a substrate (base material) temperature of 100 to 300 ° C.

Buffer layers having other components and composition ranges were also formed by the same method as for the TiAl or TiAlN buffer layer as described above.

From the result of measuring an adhesive strength of a buffer layer, shown in FIG. 21, when the base material is an aluminum alloy, it was found that all of the buffer layers evaluated in the present disclosure help in improving the adhesive strength of the coating film, compared with when there was no buffer layer.

Furthermore, the buffer layers having TiN, CrN, TiAl and TiAlN components are preferable, compared with other buffer layers, because they satisfy 10N, which is the smallest adhesive strength required for a coating film.

Among the buffer layers, the buffer layers having TiN, TiAl and TiAlN components have Ti as a main component, which is the same as that of a coating film, such as a Ti-rich amorphous or nanocomposites, and therefore it was expected that they are advantageous at least in terms of chemical compatibility between the buffet layer and the coating film.

On the other hand, when the buffer layer is CrN, an adhesive strength was measured to 18.7N, and since such a high adhesive strength of CrN satisfies most requirements of 15N or more, it is determined that CrN is most preferable.

This is a very unusual result in that CrN imparted a high adhesive strength to the coating film even though its components are different from Al of a base material as a substrate, or a Ti-rich amorphous or nanocomposites of a coating film, in other words, chemical compatibility of the buffer layer having different components is poor.

However, it is considered that CrN is advantageous for physical compatibility with the base material. First, the Bravais lattice of CrN is a face centered cubic (FCC) lattice, and the aluminum alloy, which is a base material, as a substrate in Experimental Example 4 is also advantageous for forming a coherent interface due to having the same FCC lattice.

Furthermore, it is known that the lattice constant of a CrN unit cell is approximately 0.412 Å, and the lattice constant of an aluminum unit cell is approximately 0.405 Å. When the lattice misfit (hereinafter, referred to as misfit) in lattice constant at the interface between the base material and the CrN buffer layer is calculated using the lattice constants of the Al base material and the CrN unit cell of the buffer layer, it can be seen that there is a very small misfit of approximately 1.7% at the interface. The small misfit means that there is a coherent or at least semi-coherent interface between the base material of Al matrix and the CrN buffer layer in the present disclosure. In the case of an Al alloy, when the misfit at the interface between different layers is 5% or less, the total free energy at the interface decreases so that the interface maintains a coherent or semi-coherent state. Such free energy decrease is due to high contribution of strain energy decreased by the coherent or semi-coherent interface even though interfacial energy increases by increasing interatomic chemical bonding energy due to different components of the CrN buffer layer and the Al alloy as a base material.

Therefore, it can be seen that at least a part of the source of the high adhesive strength of the CrN buffer layer in the present disclosure is caused by the same lattice structure of CrN and the Al base material as a substrate, and their very similar lattice constants.

In contrast, the above result indicates that a buffer layer for improving the adhesive strength of a coating film between a matrix and a coating film needs to have chemical compatibility in which a component and a composition range are the same as or similar to those of a matrix and/or a coating film, or physical compatibility in which a crystal structure or a lattice constant is the same as or similar to those of a matrix and/or a coating film.

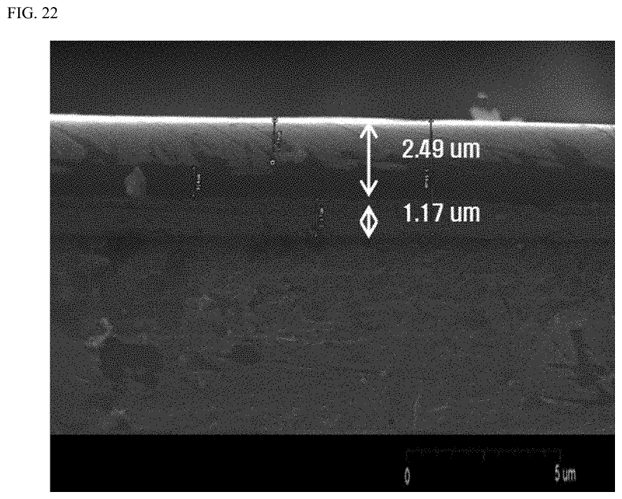

FIG. 22 shows a cross-sectional structure of a part consisting of an aluminum alloy base material/a CrN buffer layer/a Ti—Cu—Ni—N nanocomposites in Experimental Example 4 of the present disclosure.

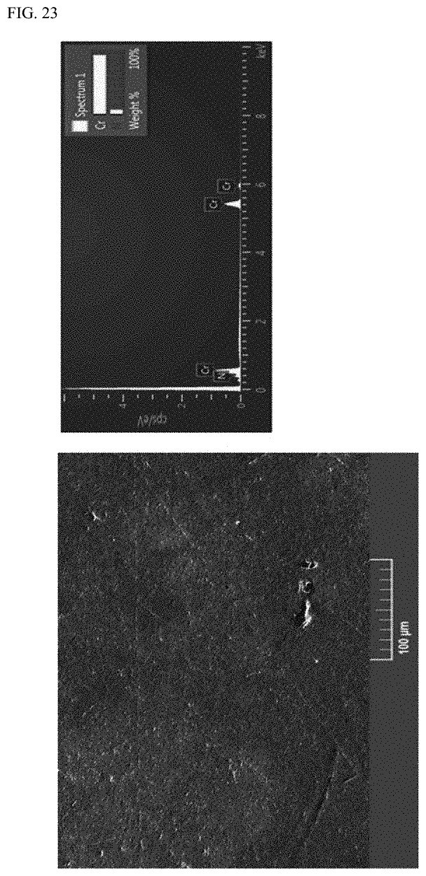

FIG. 23 shows a microstructure in a state in which a CrN buffer layer is formed on an Al alloy base material in Experimental Example 4 of the present disclosure.

As shown in FIG. 23, it can be seen that the CrN buffer layer has an excellent adhesive strength to the Al base material as a matrix, and uniformly covers the base material. In addition, the cross-sectional structure image of FIG. 22, in addition to that of FIG. 23, also shows that the relatively thick CrN buffer layer with a thickness of approximately 1.17 μm is very densely formed on the base material, and then an approximately 2.5-μm coating film is uniformly and densely formed on the buffer layer.

The microstructure images of FIGS. 22 and 23 are provided to prove that the CrN buffer layer of the present disclosure has an excellent adhesive strength between the Al base material and the Ti-rich nanocomposites.

### EXPERIMENTAL EXAMPLE 5

In Experimental Example 5 of the present disclosure, the characteristics of a coating film according to process conditions in the method of manufacturing a coating film were evaluated. In Experimental Example 5, a coating film was formed by sputtering after a target was prepared with an alloy of a Ti: 72%, Cu: 12%, Ni: 16% composition as a reference composition in the same manner as the above-described experimental examples.

Table 4 below shows the summary of the evaluation of mechanical properties of a coating film according to a bias voltage, a N₂ flow rate and a HMDSO flow rate using the target of the Ti: 72%, Cu: 12%, Ni: 16% reference composition and a spherical graphite cast iron substrate.

TABLE 4
Characteristics of coating film according to sputtering conditions

| | | | | | Adhesive | | Elastic | |
|---|---|---|---|---|---|---|---|---|
| | | N₂ | HMDSO | Bias | strength | Hardness | modulus | |
| No. | Composition | (sccm) | (sccm) | (V) | (N) | (GPa) | (GPa) | H/E |
| 1 | Ti72%—Cu12%—Ni16%—N | 25 | 0 | 75 | 25 | 17.9 | 192 | 0.093 |
| 2 | Ti72%—Cu12%—Ni16%—N | 50 | 0 | 75 | 16.1 | 26.7 | 256 | 0.104 |
| 3 | Ti72%—Cu12%—Ni16%—N | 75 | 0 | 75 | 20.5 | 15.7 | 210 | 0.075 |
| 4 | Ti72%—Cu12%—Ni16%—N | 50 | 0 | 50 | 19.9 | 14.9 | 181 | 0.082 |
| 5 | Ti72%—Cu12%—Ni16%—N | 50 | 0 | 75 | 16.1 | 26.7 | 256 | 0.104 |
| 6 | Ti72%—Cu12%—Ni16%—N | 50 | 0 | 100 | 13.6 | 25 | 217 | 0.115 |
| 7 | Ti72%—Cu12%—Ni16%—N | 50 | 0 | 150 | 3.8 | 21 | 211 | 0.100 |
| 8 | Ti72%—Cu12%—Ni16%—Si | 0 | 10 | 75 | 22.7 | 18.4 | 218 | 0.084 |
| 9 | Ti72%—Cu12%—Ni16%—Si | 0 | 20 | 75 | 2.1 | 10.4 | 148 | 0.070 |
| 10 | Ti72%—Cu12%—Ni16%—Si | 0 | 30 | 75 | 10.6 | 7.4 | 113 | 0.065 |

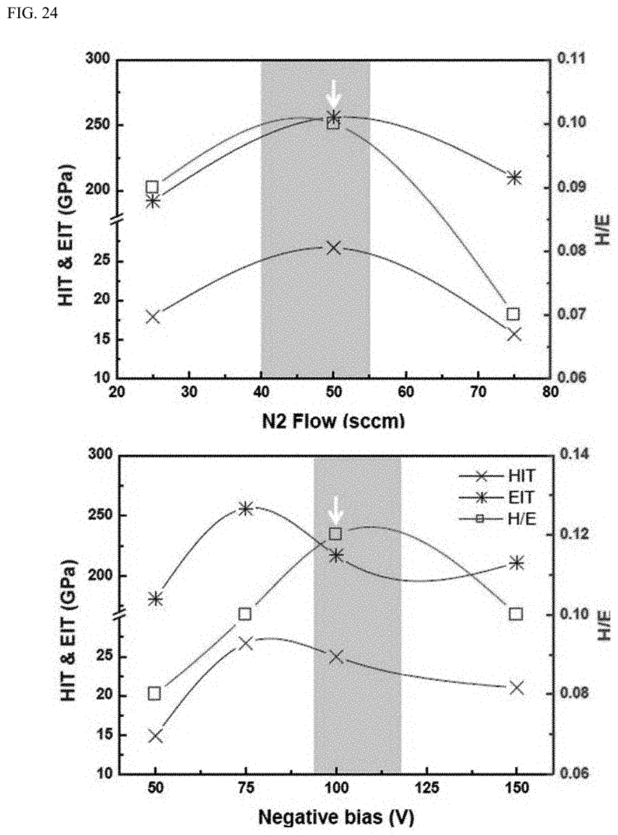

FIG. 24 shows the effects of the N₂ flow rate and the bias voltage on the coating film according to the experimental results in Table 4.

First, referring to the results of 1 to 3 of Table 4 and FIG. 24, the mechanical properties of a nanocomposites of Ti—Cu—Ni—N quaternary Ti alloys according to a N₂ flow rate were evaluated. Accordingly, it can be seen that the hardness and elastic modulus do not simply increase or decrease despite an increased N₂ flow rate, but have maximum values at the intermediate level of the N₂ flow rate. Therefore, in the method of manufacturing a coating film of the present disclosure, it can be seen that when the N₂ flow rate is 40 to 55 sccm, the maximum levels of hardness, elastic modulus and H/E are obtained.

Meanwhile, an adhesive strength did not simply increase or decrease according to a N₂ flow rate, and did show a maximum level. However, it was found that an excellent adhesive strength of 10N or more, which can be commonly used, is exhibited within a range of all N₂ flow rates examined herein.

Afterward, the results of 4 to 7 of Table 4 and FIG. 24 show the mechanical properties of nanocompositess of Ti—Cu—Ni—N quaternary Ti alloys according to the change in bias voltage.

It can be seen that, as the bias voltage increases, the hardness and the elastic modulus do not simply increase or decrease, but have maximum values at an intermediate level of the bias voltage. However, a bias voltage range having the maximum levels of hardness (H) and elastic modulus (E) is a little different from that having the maximum level of H/E. However, the most important factor for determining an actual abrasion resistance or durability of the coating film is a H/E value, and thus the maximum level of H/E is exhibited in the bias voltage range from approximately 95 to 115 V.

Meanwhile, an adhesive strength was measured to be simply reduced according to an increase in bias voltage. However, it was found that as a bias voltage is changed in the present disclosure, an excellent adhesive strength of 10N or more, which can be commonly used, is exhibited within a range in which the maximum level of H/E is exhibited, from 95 to 115V The results of 8 to 10 of Table 4 show mechanical properties of nanocompositess of Ti—Cu—Ni—Si quaternary Ti alloys according to a HMDSO flow rate. Accordingly, it is shown that, as the HMDSO flow rate increases, a hardness (H), an elastic modulus (E) and H/E of a coating film consistently decreased. Therefore, the optimal composition of Si is determined as that with an HMDSO flow rate of 10 sccm.

Next, Table 5 shows the summary of the evaluation of mechanical properties of a coating film according to a bias voltage and power using the target of the Ti: 72%, Cu: 12%, Ni: 16% reference composition, a 4007 Al substrate and a CrN buffer layer.

TABLE 5
Characteristics of coating film according to sputtering conditions

| | | | | | | Adhesive | | Elastic | |
|---|---|---|---|---|---|---|---|---|---|
| | | N₂ | HMDSO | Power | Bias | strength | Hardness | modulus | |
| No. | Composition | (sccm) | (sccm) | (kW) | (V) | (N) | (GPa) | (GPa) | H/E |
| 11 | Ti72%—Cu12%—Ni16% | 10 | 0 | 2.5 | 0 | 6.8 | 13.2 | 161 | 0.082 |
| 12 | Ti72%—Cu12%—Ni16% | 10 | 0 | 2.5 | 78 | 10.8 | 13.2 | 158 | 0.084 |
| 13 | Ti72%—Cu12%—Ni16% | 10 | 0 | 2 | 78 | 8.9 | 10.4 | 128 | 0.081 |
| 14 | Ti72%—Cu12%—Ni16% | 10 | 0 | 2 | 0 | 5.7 | 5.3 | 98 | 0.054 |
| 15 | Ti72%—Cu12%—Ni16% | 10 | 0 | 3 | 78 | 13.6 | 11.3 | 136 | 0.083 |
| 16 | Ti72%—Cu12%—Ni16% | 10 | 0 | 3 | 0 | 16.3 | 10.3 | 127 | 0.081 |
| 17 | Ti72%—Cu12%—Ni16% | 10 | 0 | 3 | 46 | 14 | 13.9 | 155 | 0.090 |
| 18 | Ti72%—Cu12%—Ni16% | 10 | 0 | 2 | 46 | 11.8 | 7.9 | 122 | 0.065 |
| 19 | Ti72%—Cu12%—Ni16% | 10 | 0 | 2.5 | 46 | 14.6 | 10.6 | 127 | 0.083 |

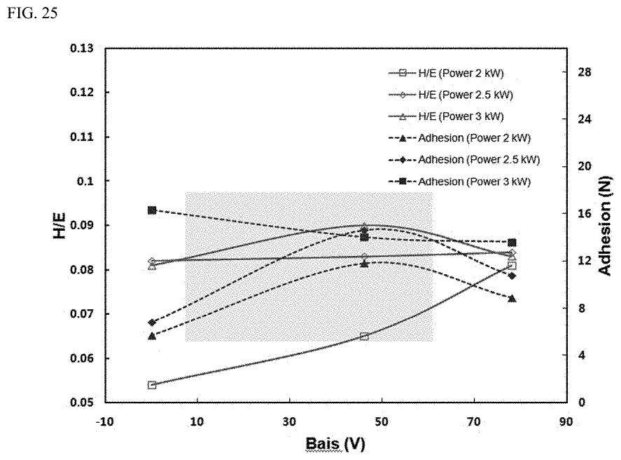

Meanwhile, FIG. 25 shows the changes in adhesive strength and H/E value of the coating film according to the change in power and bias voltage, based on the experimental results of Table 5.

Based on the H/E property that determines the abrasion resistance and durability of a coating film, first, for power, a region having the maximum H/E value at the higher power of 3 kW was observed.

Meanwhile, an adhesive strength gradually decreased relative to conventional spherical graphite cast iron as the substrate is changed into Al. The adhesive strength was generally the highest at the highest power of 3 kW, and it was confirmed that, as the bias voltage increases under the power of 3 kW, the adhesive strength tends to decrease and then converges constantly.

Accordingly, in the method of manufacturing a coating film of the present disclosure, when a substrate is Al, it was found that the maximum level of the H/E property is shown at a bias voltage of 10 to 60V, and an adhesive strength is saturated.

Next, Table 6 shows the summary of evaluation of mechanical properties of a coating film according to a reaction gas at constant bias voltage and power using the target of the Ti: 72%, Cu: 12%, Ni: 16% reference composition, a 4007 Al substrate and a CrN buffer layer.

TABLE 6
Characteristics of coating film according to sputtering conditions

| | | | | Adhesive | | Elastic | |
|---|---|---|---|---|---|---|---|
| | | N₂ | HMDSO | strength | Hardness | modulus | |
| No. | Composition | (sccm) | (sccm) | (N) | (GPa) | (GPa) | H/E |
| 20 | Ti72%—Cu12%—Ni16%—N | 10 | 0 | 6.7 | 11.8 | 143 | 0.083 |
| 21 | Ti72%—Cu12%—Ni16%—Si—N | 5 | 5 | 11.1 | 8.5 | 118 | 0.072 |
| 22 | Ti72%—Cu12%—Ni16%—Si—N | 10 | 5 | 17.3 | 14.6 | 156 | 0.094 |
| 23 | Ti72%—Cu12%—Ni16%—Si—N | 10 | 10 | 15.9 | 12.2 | 150 | 0.081 |
| 24 | Ti72%—Cu12%—Ni16%—Si—N | 5 | 10 | 15.5 | 10.3 | 142 | 0.073 |
| 25 | Ti72%—Cu12%—Ni16%—N | 5 | 0 | 10.4 | 8.9 | 124 | 0.072 |
| 26 | Ti72%—Cu12%—Ni16% | 0 | 0 | 2.4 | 8.2 | 128 | 0.064 |
| 27 | Ti72%—Cu12%—Ni16%—Si | 0 | 5 | 1.3 | 6.3 | 109 | 0.058 |
| 28 | Ti72%—Cu12%—Ni16%—Si | 0 | 10 | 2.6 | 6.1 | 107 | 0.057 |

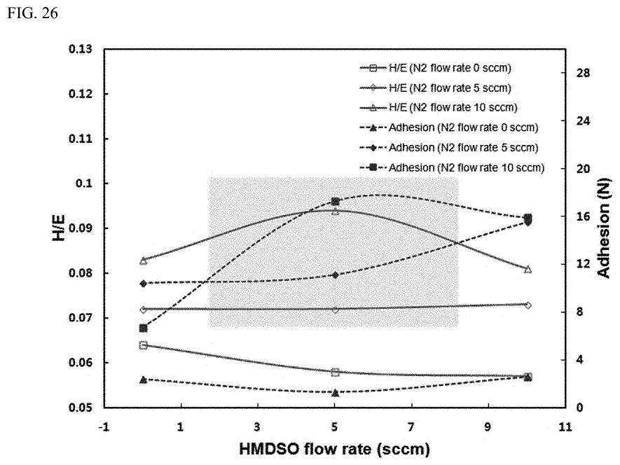

Meanwhile, FIG. 26 shows the changes in adhesive strength and H/E value of the coating film according to the changes in N₂ and HMDSO flow rates based on the experimental results of Table 6.

Based on the H/E property that determines the abrasion resistance and durability of a coating film, first, it was observed that the coating film has the highest H/E value when N₂ flow rate is 10 sccm, regardless of the HMDSO flow rate.

Meanwhile, an adhesive strength generally decreased compared to conventional spherical graphite cast iron as a substrate is changed into Al. It was observed that, when the N₂ flow rate is the highest at 10 sccm, the coating film has highest adhesive strength.

In addition, it can be seen that the H/E value and the adhesive strength did not simply increase or decrease as a HDMSO flow rate increases, and have the maximum values at an intermediate level of the HDMSO flow rate. Particularly, it was found that, when the HDMSO flow rate is in a range of 2 to 8 sccm, both of the H/E value and the adhesive strength had maximum values.

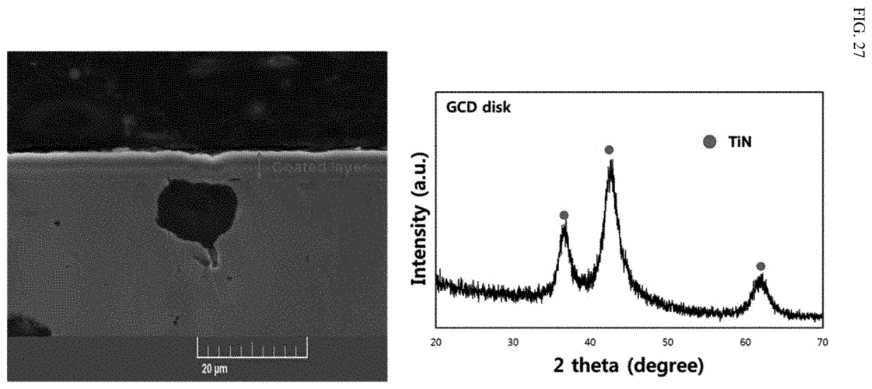

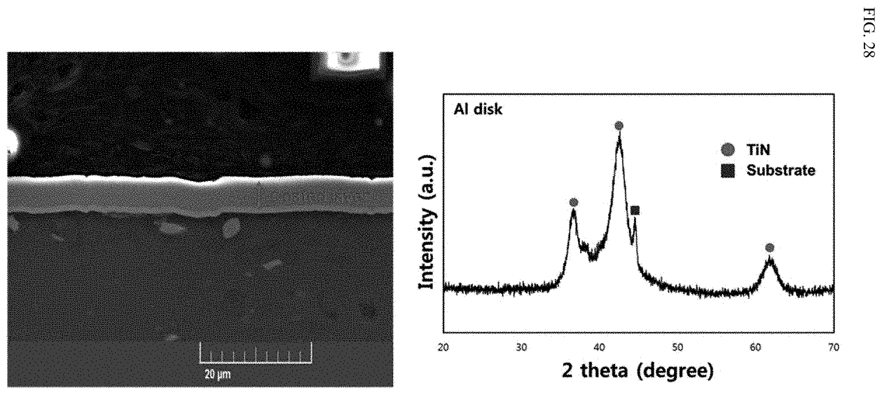

FIGS. 27 and 28 show cross-sectional microstructure images and XRD results of coating films manufactured by reactive sputtering with an HDMSO gas and a N₂ gas using a target of Ti: 72%, Cu: 12%, Ni: 16% reference composition and spherical graphite cast iron and a 4007 Al alloy as substrates, respectively.

As shown in FIGS. 27 and 28, it can be seen that a uniform and dense coating film is formed regardless of the type of substrate. In addition, some peaks were observed in the XRD patterns, and most of these peaks were found to be diffraction peaks formed by TiN. In addition, diffraction peaks formed by the substrate were found in some parts of the Al alloy substrate. From the microstructure and XRD pattern results of the coating film and the above-described XRD pattern results of the TiCuNiSi alloy, it can be seen that the coating film according to the present disclosure is formed of a nano-composite including nano-sized crystals consisting of a TiN component in the TiCuNiSi amorphous alloy matrix.

<Compressor>

Hereinafter, a compressor coated with the nanocomposites suggested in the present disclosure or including a nanocomposites-coated part will be described.

The coating film of the present disclosure can be applied between all movable parts or components. In addition, the parts to which the coating film of the present disclosure is applied can be applied to all parts (e.g., an inner ring) in a cylinder.

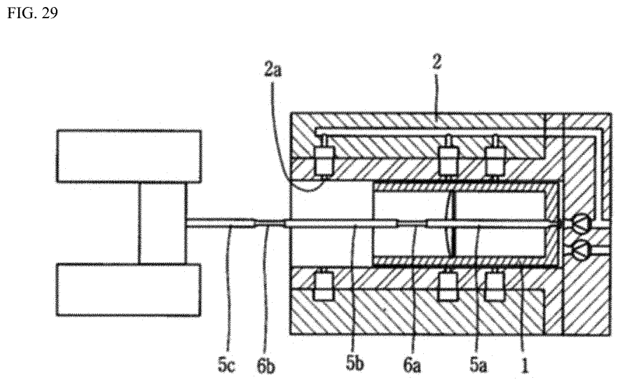

FIG. 29 is a partial cross-sectional view of a general compressor having a gas bearing, related to the present disclosure. In the present disclosure, as the simplest example, a reciprocating compressor in which a piston linearly reciprocates inside the cylinder, absorbs a refrigerant and then discharges it after compression is suggested.

As shown in FIG. 29, the configuration in which a part of a compressed gas between the piston 1 and the cylinder 2 is bypassed to form a gas bearing between them is widely known technology. Such technology may not only simplify a lubricating structure of the compressor due to no need of a separate oil supplier, compared with an oil lubricating method that provides oil between the piston 1 and the cylinder 2, but also consistently maintain the performance of the compressor by preventing an oil shortage according to an operating condition. In addition, since there is no need of space that can contain oil in a casing of the compressor, there is an advantage that the compressor can be miniaturized and the installation direction of the compressor can be freely designed.

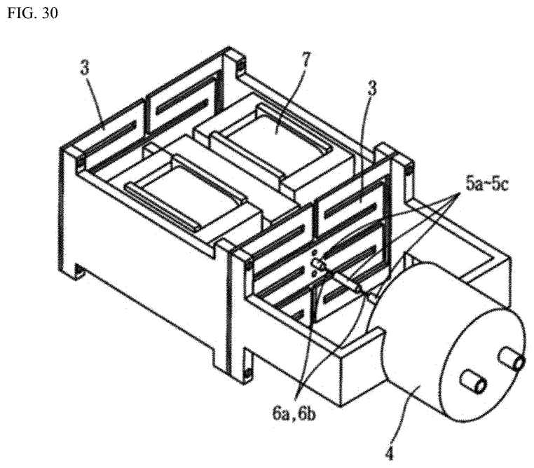

On the other hand, when the gas bearing is applied to a reciprocating compressor, as shown in FIG. 30, a leaf spring 3 or another type of spring is applied for resonant motion of a piston. However, in this case, since members should be connected with a flexible connecting bar or a plurality of connecting bars should be connected with a linker, material costs and assembly work increase.

However, due to the characteristics of the leaf spring, the displacement in the direction of piston movement (longitudinal displacement) greatly occurs, whereas the displacement perpendicular to the direction of piston movement (transverse displacement) rarely occurs. Therefore, when the piston is arranged to move in a vertical direction, it hangs down in a vertical direction, and thus the initial position may change.

Meanwhile, the nanocomposites-coated part according to the present disclosure can be applied to all parts of a compressor shown in FIGS. 21 and 22. When the amorphous alloy of the present disclosure is coated on the surfaces of the piston and cylinder, due to a high hardness, which is inherent in the nanocomposites and a low elastic modulus of an amorphous matrix, friction and abrasion properties are not only enhanced, but also resistance is improved due to destruction caused by high toughness. In addition, when the coating film consisting of a nanocomposites of the present disclosure is applied to other parts inside or outside the cylinder, the displacement for the resonant movement of the piston of the compressor may be elastically absorbed into the inner part without delivery to the spring, and thus the reliability of the part itself caused by high toughness may be greatly enhanced as well as the positional stability of the piston and the compressor.

Meanwhile, a part having the nanocomposites coating film of the present disclosure, that is, a base material of the coating film, is not particularly limited. However, the base material preferably includes at least one of currently commercially used steel, casting, an Al-containing alloy and a magnesium-containing alloy. This is because a metal such as the steel, the casting, the Al-containing alloy, or the magnesium-containing alloy has a side effect of being able to achieve GFA of the coating film due to high thermal conductivity.

As above, the present disclosure has been described with reference to the exemplified drawings, but it is clear that the present disclosure is not limited by the examples and drawings disclosed herein, and can be modified in various ways by those of ordinary skill in the art within the scope of the technical idea of the present disclosure. In addition, even though the action effect according to the configuration of the present disclosure has not been clearly described while describing the examples of the present disclosure above, it is obvious that effects that can be predicted by the corresponding configuration are also be recognized.

1. A film, comprising:
an amorphous matrix that includes titanium (Ti) as a main component of the film; and
a plurality of nanocomposites that include nanocrystals, wherein the nanocrystals include a titanium nitride (TiN) component and are located in the amorphous matrix.

2. (canceled)

3. (canceled)

4. The film of claim 1, wherein the amorphous matrix is a titanium-copper-nickel-molybdenum (Ti—Cu—Ni—Mo) quaternary alloy.

5. The film of claim 4, wherein the amorphous matrix has a composition containing: 48.5 to 64.4% Ti; 14.3 to 40.6%, Cu; 6.7 to 19.8% Ni; and 1 to 5%, Mo.

6. A method, comprising:
providing and installing a base material into a sputtering device; and
forming a film on the base material surface by sputtering a target in the sputtering device while introducing nitrogen or a reaction gas that includes nitrogen into the sputtering device,
wherein the film comprises an amorphous matrix that includes titanium (Ti) as a main component of the film and a plurality of nanocomposites that include nanocrystals, wherein the nanocrystals include a titanium nitride (TiN) component and are located in the amorphous matrix.

7. (canceled)

8. (canceled)

9. The method of claim 6, wherein the amorphous matrix is a titanium-copper-nickel-molybdenum (Ti—Cu—Ni—Mo) quaternary alloy.

10. The method of claim 9, wherein the amorphous matrix has a composition containing: 48.5 to 64.4%, Ti; 14.3 to 40.6%, Cu; 6.7 to 19.8% Ni; and 1 to 5%, Mo.

11. The film: of claim 1, wherein the amorphous matrix further includes silicon (Si).

12. The film of claim 11, wherein the amorphous matrix is a Ti—Cu—Ni—Si quaternary alloy.

13. The film of claim 12, wherein the amorphous matrix has a composition containing: 59.2 to 80%, Ti; 4.6 to 20%, Cu; 4.6 to 25% Ni; and 9% or less Si, and wherein the composition of Si is higher than 0.

14. The film of claim 11, wherein the amorphous matrix is a Ti—Cu—Ni—Mo—Si quinary alloy.

15. The film of claim 14, wherein the matrix has a composition containing: 48.5 to 65Ti; 14.3 to 41%, Cu; 6.7 to 20% Ni; 1% or less Si; and 1 to 5%, expressed as at%.% Mo, and wherein the composition of Si is higher than 0.

16. The method of claim 13, wherein forming the film further comprises introducing a reaction gas that includes silicon (Si) into the sputtering device.

17. The method of claim 16, wherein the amorphous matrix is a Ti—Cu—Ni—Si quaternary alloy.

18. The method of claim 17, wherein the amorphous matrix has a composition containing: 59.2 to 80%, Ti; 4.6 to 20%, Cu; 4.6 to 25% Ni; and 9% or less Si, and wherein the composition of Si is higher than 0.

19. The method of claim 16, wherein the amorphous matrix is a Ti—Cu—Ni—Mo—Si quinary alloy.

20. The method of claim 19, wherein the amorphous matrix has a composition containing: 48.5 to 65%, Ti; 14.3 to 41% Cu; 6.7 to 20%, Ni; 1% or less Si; and 1 to 5% Mo, and wherein the composition of Si is higher than 0.

21-27. (canceled)

28. An apparatus, comprising:
an aluminum (Al) alloy base material;
a buffer layer located on the base material; and
the film of claim 1 that is located on the buffer layer.

29. The apparatus of claim 28, wherein the buffer layer has, based on its composition of the Al alloy base material and/or at least one of components of the film, chemical compatibility with the Al alloy base material and/or the film.

30. (canceled)

31. (canceled)

32. The apparatus of claim 28, wherein the buffer layer has, based on its lattice structure being the same as the Al alloy base material and/or the film, physical compatibility with the Al alloy base material and/or the film.

33. The apparatus of claim 28, wherein the buffer layer has a 5% or less misfit in lattice constant compared to the base material or the film.

34-47. (canceled)
